(19) United States
(12) Patent Application Publication
(10) Pub. No.: US 2024/0312964 A1
(43) Pub. Date: Sep. 19, 2024

(54) DISPLAY DEVICE AND METHOD OF FABRICATING THE SAME

(71) Applicant: Samsung Display Co., LTD., Yongin-si (KR)

(72) Inventors: Hyung Il JEON, Yongin-si (KR); Dae Ho SONG, Yongin-si (KR); Jin Woo CHOI, Yongin-si (KR)

(21) Appl. No.: 18/544,881

(22) Filed: Dec. 19, 2023

(30) Foreign Application Priority Data
Mar. 16, 2023 (KR) 10-2023-0034603

(51) Int. Cl. H01L 25/075; H01L 27/12; H01L 33/50; H01L 33/62

(52) U.S. Cl. CPC H01L 25/0753; H01L 27/124; H01L 33/505; H01L 33/62

(57) ABSTRACT

A display device includes comprises a substrate comprising a display area and a non-display area, a pixel electrode located on the substrate, a light-emitting element located on the pixel electrode and extending in a thickness direction of the substrate, a color conversion layer located on the light-emitting element and comprising wavelength conversion particles that convert first light emitted from the light-emitting element into second light or third light and a common electrode located on the light-emitting element and surrounding side surfaces of the color conversion layer and side surfaces of the light-emitting element.

### CROSS-REFERENCED TO RELATED APPLICATION

The present application claims priority to, and the benefit of, Korean Patent Application No. 10-2023-0034603, filed on Mar. 16, 2023, in the Korean Intellectual Property Office, the content of which in its entirety is herein incorporated by reference.

### BACKGROUND

### 1. Field

The present disclosure relates to a display device.

### 2. Description of Related Art

As the information society develops, demands for display devices for displaying images are increasing in various forms. The display devices may be flat panel displays, such as liquid crystal displays, field emission displays, and light-emitting displays. The light-emitting displays may include an organic light-emitting display including an organic light-emitting diode element as a light-emitting element, or an inorganic light-emitting display including an inorganic semiconductor element as a light-emitting element,

Recently, a head-mounted display including a light-emitting display has been developed. The head-mounted display is a virtual reality (VR) or augmented reality (AR) glasses-type monitor device that is worn in the form of glasses or a helmet and forms a focus at a short distance in front of a user's eyes.

A high-resolution ultra-small light-emitting diode display panel including an ultra-small light-emitting diode element is applied to the head-mounted display. Because the ultra-small light-emitting diode element emits light of a single color, the ultra-small light-emitting diode display panel may include a color conversion layer that converts a wavelength of light emitted from the ultra-small light-emitting diode element to display various colors.

### SUMMARY

Aspects of the present disclosure provide a display device capable of reducing or preventing the likelihood of light emitted from adjacent light-emitting elements being mixed by using a common electrode without using a separate reflective layer and a method of manufacturing the display device.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided display device including a substrate including a display area and a non-display area, a pixel electrode above the substrate, a light-emitting element above the pixel electrode, and extending in a thickness direction of the substrate, a color conversion layer above the light-emitting element, and including wavelength conversion particles for converting first light from the light-emitting element into second light or third light, and a common electrode on the light-emitting element, and surrounding side surfaces of the color conversion layer and side surfaces of the light-emitting element.

The common electrode may include a reflective material.

The color conversion layer may include a third semiconductor layer defining pores that accommodate the wavelength conversion particles.

The light-emitting element may sequentially include a first semiconductor layer, an active layer, and a second semiconductor layer.

The display device may further include a first insulating layer surrounding side surfaces of the first semiconductor layer and the active layer.

The common electrode may include a first common electrode on the first insulating layer to surround the side surfaces of the first semiconductor layer and the active layer, directly contacting the second semiconductor layer, and covering a non-light-emitting area of the display area, and a second common electrode surrounding the side surfaces of the color conversion layer, and covering the non-light-emitting area of the display area, wherein the non-light-emitting area is a portion of the display area excluding a light-emitting area corresponding to the light-emitting element.

The second common electrode may be on the first common electrode in the non-light-emitting area, and may contact the first common electrode in the non-light-emitting area.

The first common electrode may cover a portion of a lower surface of the light-emitting element.

The light-emitting element may further include a connection electrode below the lower surface, and electrically insulated from the first common electrode.

The first common electrode may be spaced apart from the connection electrode.

The first common electrode may be spaced apart from the connection electrode, wherein a second insulating layer fills a space between the first common electrode and the connection electrode.

The first common electrode may contact the connection electrode, wherein an oxide layer is in a contact area between the first common electrode and the connection electrode.

The display device may further include a common connection electrode in the non-display area and contacting the common electrode.

According to another aspect of the present disclosure, a display device includes a substrate including a pixel circuit, a first light-emitting element, a second light-emitting element, and a third light-emitting element above the substrate, and each including a first semiconductor layer, an active layer, a second semiconductor layer, and a third semiconductor layer, a first insulating layer surrounding the first semiconductor layer and the active layer of each of the first light-emitting element, the second light-emitting element, and the third light-emitting element, and a common electrode continuously above the first light-emitting element, the second light-emitting element, and the third light-emitting element, including a reflective material, and on the first insulating layer to surround the first semiconductor layer, the active layer, the second semiconductor layer, and the third semiconductor layer of each of the first light-emitting element, the second light-emitting element, and the third light-emitting element.

The third semiconductor layer may define pores that accommodate wavelength conversion particles.

The first light-emitting element, the second light-emitting element, and the third light-emitting element may be configured to emit first light, wherein the third semiconductor layer of the second light-emitting element accommodates first wavelength conversion particles for converting the first light into second light in the pores, and wherein the third semiconductor layer of the third light-emitting element accommodates second wavelength conversion particles for converting the first light into third light in the pores.

The display device may further include a color filter for transmitting the first light is above the first light-emitting element, a color filter for transmitting the second light is above the second light-emitting element, and a color filter for transmitting the third light is above the third light-emitting element.

The common electrode may include a first common electrode and a second common electrode, wherein the first common electrode includes a first portion on the first insulating layer to surround side surfaces of the first semiconductor layer and the active layer, and directly contacting the second semiconductor layer, and a second portion covering a space between the light-emitting elements, and wherein the second common electrode includes a third portion surrounding side surfaces of the third semiconductor layer, and a fourth portion covering the space between the light-emitting elements, and on the third portion to contact the third portion.

According to another aspect of the present disclosure, there is provided a method of manufacturing a display device, the method including sequentially forming a third semiconductor layer, a second semiconductor layer, an active layer, and a first semiconductor layer above a substrate, forming light-emitting elements by etching the second semiconductor layer, the active layer, and the first semiconductor layer, forming an insulating layer surrounding side surfaces of the first semiconductor layer and the active layer, forming a first common electrode above the substrate covering the insulating layer and the second semiconductor layer, and defining an opening on a surface of each light-emitting element, forming a color conversion layer defining pores by applying an electric field to the third semiconductor layer, etching the third semiconductor layer to correspond to each of the light-emitting elements, and injecting wavelength conversion particles, and forming a second common electrode covering side surfaces of the color conversion layer, and contacting the first common electrode.

The forming the color conversion layer may include etching the third semiconductor layer such that an upper surface of the third semiconductor layer is aligned with an upper surface of the second semiconductor layer in contact with the third semiconductor layer.

The forming the insulating layer may include forming a sacrificial layer between the light-emitting elements to cover the third semiconductor layer and side surfaces of the second semiconductor layer, forming the insulating layer to cover an upper surface and the side surfaces of the first semiconductor layer, side surfaces of the active layer, and an upper surface of the sacrificial layer, anisotropically etching the insulating layer to cover the upper and side surfaces of the first semiconductor layer and the side surfaces of the active layer, and removing the sacrificial layer.

The forming of the first common electrode may include forming a common electrode layer on the insulating layer, forming an opening by removing portions of the insulating layer and the common electrode layer on an upper surface of the first semiconductor layer, and forming a connection electrode on the opening.

### BRIEF DESCRIPTION OF THE DRAWINGS

These and/or other aspects will become apparent and more readily appreciated from the following description of the embodiments, taken in conjunction with the accompanying drawings in which:

FIG. 1 is a layout view of a display device according to one or more embodiments;

FIG. 2 is a detailed layout view of area A of FIG. 1;

FIG. 3 is a layout view illustrating pixels of a display panel according to one or more embodiments;

FIG. 4 is a cross-sectional view of an example of the display panel taken along the line A-A′ of FIG. 2;

FIG. 5 is an equivalent circuit diagram of a pixel of the display device according to one or more embodiments;

FIG. 6 is an equivalent circuit diagram of a pixel of a display device according to one or more embodiments;

FIG. 7 is an equivalent circuit diagram of a pixel of a display device according to one or more embodiments;

FIG. 8 is a cross-sectional view of an example of the display panel taken along the line B-B′ of FIG. 2;

FIG. 9 is a plan view of an example of a light-emitting element layer according to one or more embodiments;

FIG. 10 is a cross-sectional view of an example of a color conversion layer and a light-emitting element of the display panel according to one or more embodiments;

FIG. 11 is a cross-sectional view of an example of a light-emitting element layer according to one or more embodiments;

FIG. 12 is a view of an example of a light-emitting element layer according to one or more embodiments of the present disclosure;

FIG. 13 is a view of an example of a light-emitting element layer according to one or more embodiments of the present disclosure;

FIG. 14 is a cross-sectional view of an example of a display panel according to one or more embodiments, taken along the line A-A′ of FIG. 2;

FIG. 15 is a plan view illustrating an example of color filters and light-emitting elements of FIG. 14;

FIG. 16 is a flowchart illustrating a method of manufacturing a display panel according to one or more embodiments; and

FIGS. 17 through 32 are cross-sectional views illustrating the method of manufacturing the display panel according to one or more embodiments.

FIG. 33 is an example diagram schematically showing a virtual reality device including a display device according to one or more embodiments.

FIG. 34 is an example diagram schematically showing a smart device including a display device according to one or more embodiments.

FIG. 35 is a diagram of an example schematically showing a vehicle including a display device according to one or more embodiments.

FIG. 36 is a diagram of an example schematically showing a transparent display device including a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The present disclosure covers all modifications, equivalents, and replacements within the idea and technical scope of the present disclosure. Further, each of the features of the various embodiments of the present disclosure may be combined or combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

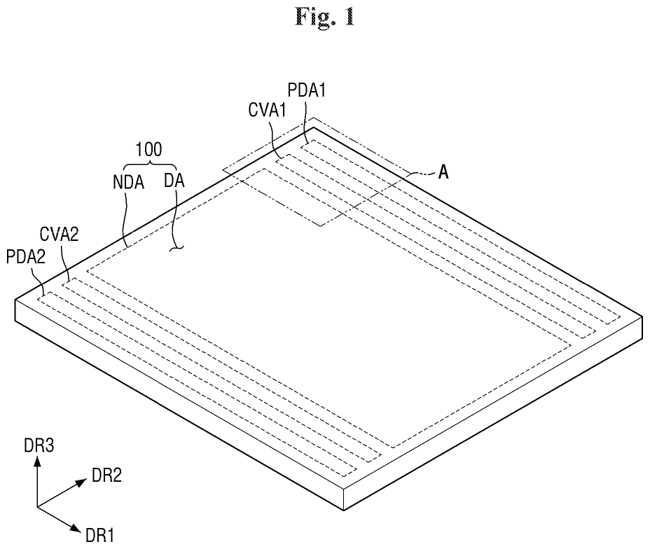

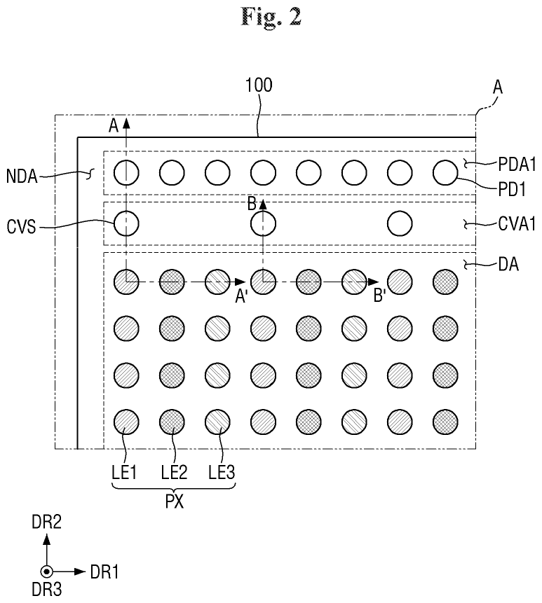

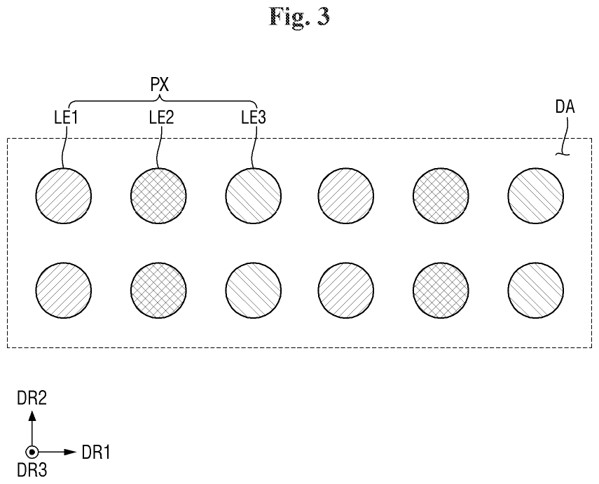

FIG. 1 is a layout view of a display device according to one or more embodiments. FIG. 2 is a detailed layout view of area A of FIG. 1. FIG. 3 is a layout view illustrating pixels PX of a display panel 100 according to one or more embodiments.

In FIGS. 1 through 3, the display device according to one or more embodiments is mainly described as an ultra-small light-emitting diode display device (or a micro- or nano-light-emitting diode display device) including an ultra-small light-emitting diode (or a micro- or nano-light-emitting diode) as a light-emitting element, but embodiments of the present specification are not limited thereto.

In addition, in FIGS. 1 through 3, the display device according to one or more embodiments is mainly described as a light-emitting diode on silicon (LEDoS) display device in which light-emitting diodes are arranged as light-emitting elements on a semiconductor circuit board 110 formed by a semiconductor process using a silicon wafer. However, it should be noted that embodiments of the present specification are not limited thereto.

In addition, in FIGS. 1 through 3, a first direction DR1 refers to a horizontal direction of the display panel 100, a second direction DR2 refers to a vertical direction of the display panel 100, and a third direction DR3 refers to a thickness direction of the display panel 100 or to a thickness direction of the semiconductor circuit board 110. In this case, “left,” “right,” “upper,” and “lower” refer to directions when the display panel 100 is seen in plan view. For example, a “right side” refers to one side in the first direction DR1, a “left side” refers to the other side in the first direction DR1, an “upper side” refers to one side in the second direction DR2, and a “lower side” refers to the other side in the second direction DR2. In addition, “top” refers to one side in the third direction DR3, and “bottom” refers to the other side in the third direction DR3.

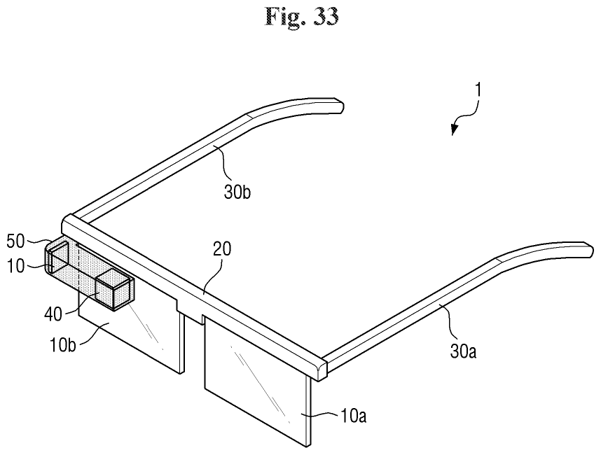

Referring to FIGS. 1 through 3, the display device 10 (e.g., see FIGS. 33 to 36) according to one or more embodiments includes the display panel 100 including a display area DA and a non-display area NDA.

The display panel 100 may have a quadrilateral planar shape having long sides extending in the first direction DR1, and short sides extending in the second direction DR2. However, the planar shape of the display panel 100 is not limited thereto, and the display panel 100 may also have a polygonal, circular, oval, or irregular planar shape other than the quadrilateral shape.

The display area DA may be an area where an image is displayed, and the non-display area NDA may be an area where no image is displayed. The planar shape of the display area DA may follow the planar shape of the display panel 100. In FIG. 1, the planar shape of the display area DA is a quadrilateral shape. The display area DA may be located in a central area of the display panel 100. The non-display area NDA may be located around the display area DA. The non-display area NDA may surround the display area DA.

The display area DA of the display panel 100 may include a plurality of pixels PX. Each of the pixels PX may be defined as a minimum light-emitting unit that can display white light.

Each of the pixels PX may include first through third light-emitting elements LE1, LE2, and LE3 that emit light. In one or more embodiments of the present specification, each of the pixels PX includes three light-emitting elements LE1, LE2, and LE3, but embodiments of the present specification are not limited thereto. In addition, although each of the first through third light-emitting elements LE1, LE2, and LE3 has a circular planar shape, embodiments of the present specification are not limited thereto.

The first light-emitting element LE1 may emit first light. The first light may be light in a blue wavelength band. For example, a main peak wavelength (B-peak) of the first light may be about 370 nm to about 460 nm, but embodiments of the present specification are not limited thereto.

The second light-emitting element LE2 may emit second light. The second light may be light in a green wavelength band. For example, a main peak wavelength (G-peak) of the second light may be located at about 480 nm to about 560 nm, but embodiments of the present specification are not limited thereto.

The third light-emitting element LE3 may emit the first light. The first light may be light in the blue wavelength band. For example, the main peak wavelength (B-peak) of the first light may be located at about 370 nm to about 460 nm, but embodiments of the present specification are not limited thereto. In the current one or more embodiments, the third light-emitting element LE3 may emit the first light, but the first light emitted from the third light-emitting element LE3 may be converted into third light by a wavelength conversion layer and/or a color filter that will be described later. The third light may be light in a red wavelength band. The red wavelength band may be about 600 nm to about 750 nm.

The first light-emitting elements LE1, the second light-emitting elements LE2, and the third light-emitting elements LE3 may be alternately arranged in the first direction DR1. For example, the first light-emitting elements LE1, the second light-emitting elements LE2, and the third light-emitting elements LE3 may be arranged in the order of the first light element LE1, the second light-emitting element LE2, and the third light-emitting element LE3 in the first direction DR1. The first light elements LE1 may be arranged in the second direction DR2. The second light-emitting elements LE2 may be arranged in the second direction DR2. The third light-emitting elements LE3 may be arranged in the second direction DR2.

The non-display area NDA may include a first common voltage supply area CVA1, a second common voltage supply area CVA2, a first pad portion PDA1, and a second pad portion PDA2.

The first common voltage supply area CVA1 may be located between the first pad portion PDA1 and the display area DA. The second common voltage supply area CVA2 may be located between the second pad portion PDA2 and the display area DA. Each of the first common voltage supply area CVA1 and the second common voltage supply area CVA2 may include a plurality of common voltage supply units CVS connected to a common electrode CE. A common voltage may be supplied to the common electrode CE through the common voltage supply units CVS.

The common voltage supply units CVS of the first common voltage supply area CVA1 may be electrically connected to any one of first pads PD1 of the first pad portion PDA1. That is, the common voltage supply units CVS of the first common voltage supply area CVA1 may receive a common voltage from any one of the first pads PD1 of the first pad portion PDA1.

The common voltage supply units CVS of the second common voltage supply area CVA2 may be electrically connected to any one of second pads of the second pad portion PDA2. That is, the common voltage supply units CVS of the second common voltage supply area CVA2 may receive a common voltage from any one of the second pads of the second pad portion PDA2.

In FIG. 1, the common voltage supply areas CVA1 and CVA2 are located on both sides of the display area DA, but embodiments of the present specification are not limited thereto. For example, the common voltage supply areas CVA1 and CVA2 may also surround the display area DA.

The first pad portion PDA1 may be located on an upper side of the display panel 100. The first pad portion PDA1 may include the first pads PD1 connected to an external circuit board.

The second pad portion PDA2 may be located on a lower side of the display panel 100. The second pad portion PDA2 may include the second pads for connection to an external circuit board. The second pad portion PDA2 may also be omitted.

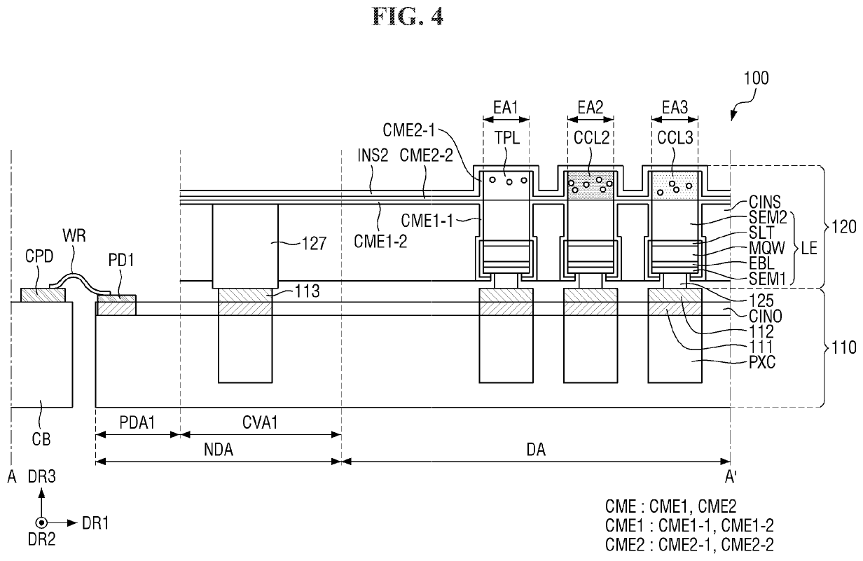

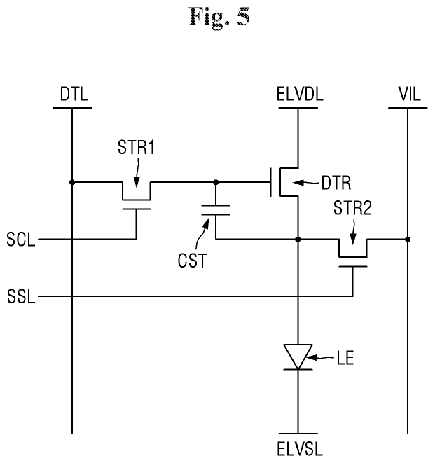

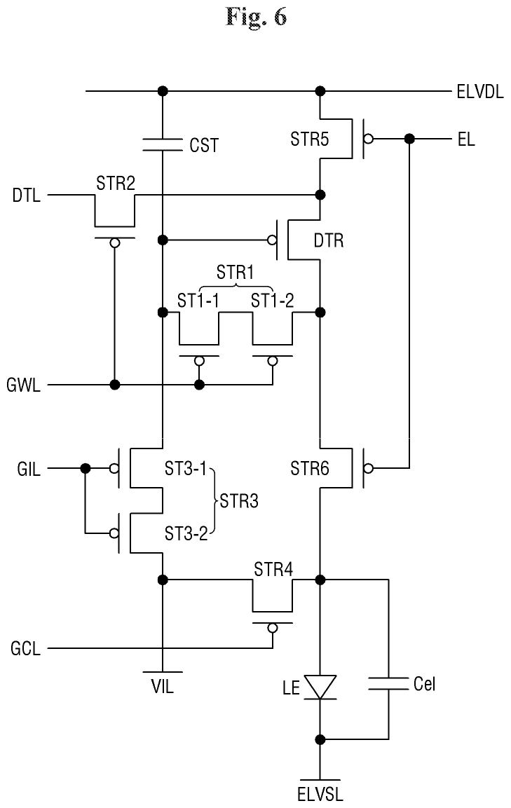

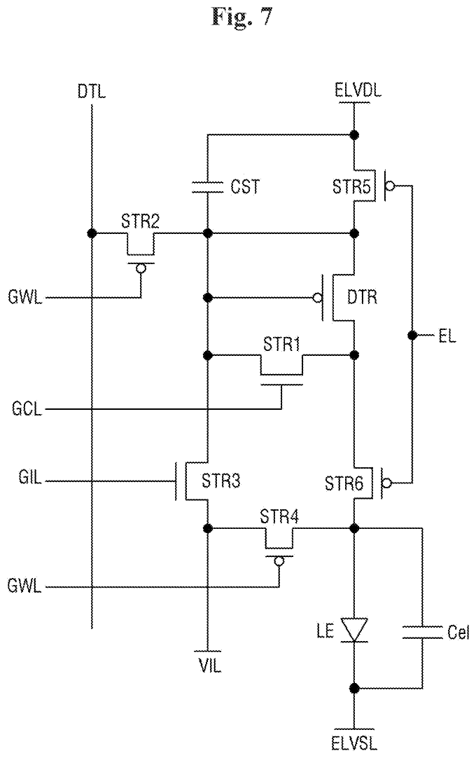

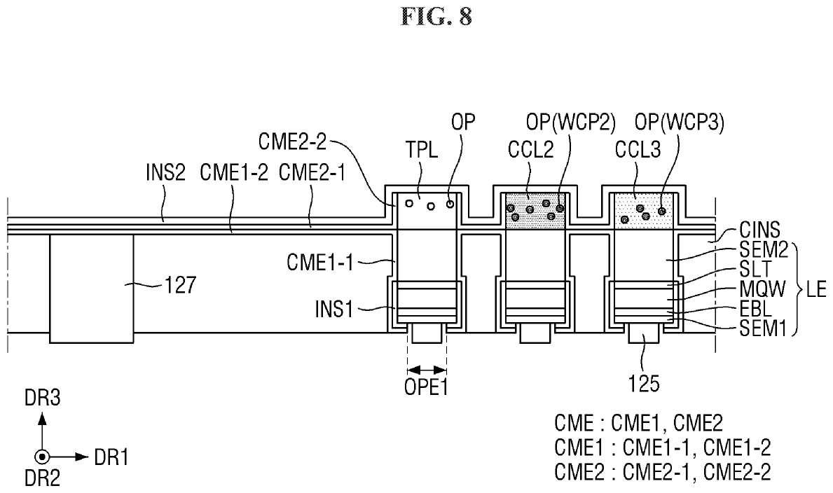

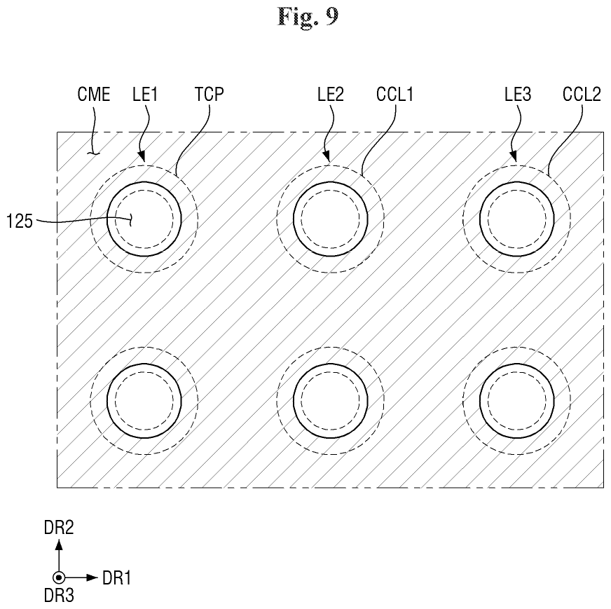

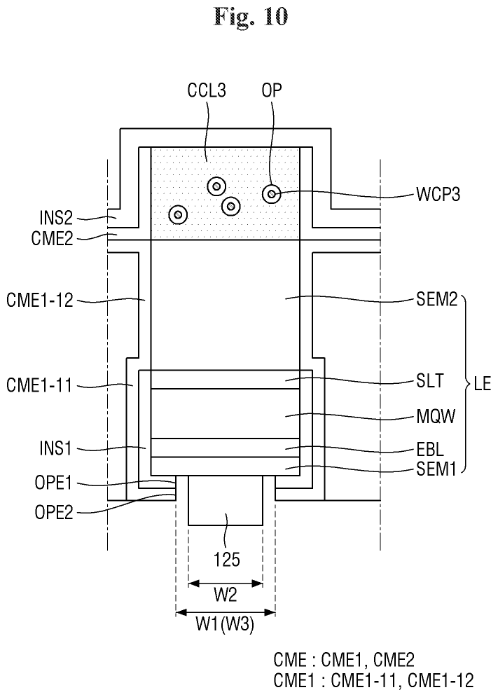

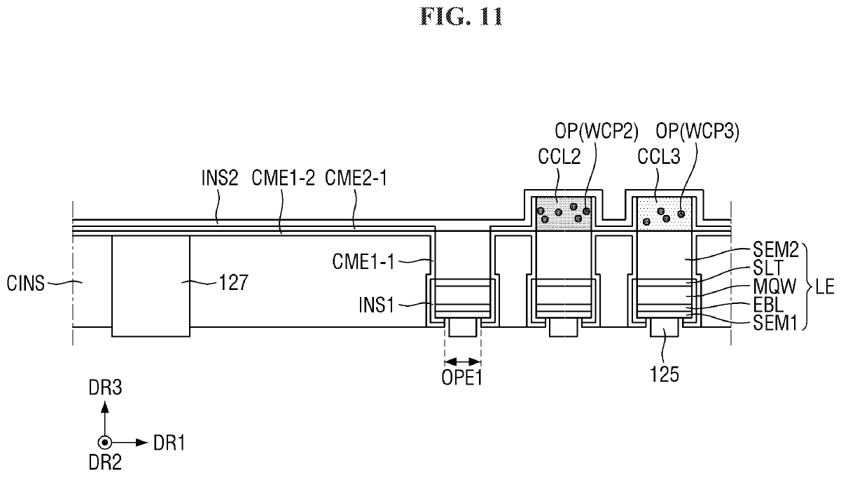

FIG. 4 is a cross-sectional view of an example of the display panel 100 taken along the line A-A′ of FIG. 2. FIG. 5 is an equivalent circuit diagram of a pixel of the display device according to one or more embodiments. FIG. 6 is an equivalent circuit diagram of a pixel of a display device according to one or more embodiments. FIG. 7 is an equivalent circuit diagram of a pixel of a display device according to one or more embodiments. FIG. 8 is a cross-sectional view of an example of the display panel 100 taken along the line B-B′ of FIG. 2. FIG. 9 is a plan view of an example of a light-emitting element layer 120 according to one or more embodiments. FIG. 10 is a cross-sectional view of an example of a color conversion layer and a light-emitting element of the display panel 100 according to one or more embodiments. FIG. 11 is a cross-sectional view of an example of a light-emitting element layer according to one or more embodiments.

Referring to FIGS. 4 through 10, the display panel 100 according to one or more embodiments may include the semiconductor circuit board 110 and the light-emitting element layer 120.

The semiconductor circuit board 110 may include a plurality of pixel circuit units PXC, pixel electrodes 111, contact electrodes 112, the first pads PD1, a common contact electrode 113, and a circuit-insulating layer CINO. In a modified example, the contact electrodes 112 and/or the circuit-insulating layer CINO may be omitted.

The semiconductor circuit board 110 may be a silicon wafer substrate formed using a semiconductor process, and may be a first substrate. The pixel circuit units PXC of the semiconductor circuit board 110 may be formed using a semiconductor process.

The pixel circuit units PXC may be located in the display area DA and in the non-display area NDA. Each of the pixel circuit units PXC may be connected to a corresponding pixel electrode 111. That is, the pixel circuit units PXC and the pixel electrodes 111 may be connected one-to-one to each other. The pixel circuit units PXC may respectively overlap light-emitting elements LE in the third direction DR3.

Each of the pixel circuit units PXC may include at least one transistor formed using a semiconductor process. In addition, each of the pixel circuit units PXC may further include at least one capacitor formed using a semiconductor process. The pixel circuit units PXC may include, for example, a complementary metal oxide semiconductor (CMOS) circuit. Each of the pixel circuit units PXC may apply a pixel voltage or an anode voltage to a corresponding pixel electrode 111.

Referring to FIG. 5, each of a plurality of pixel circuit units PXC according to one or more embodiments may include three transistors DTR, STR1, and STR2 and one storage capacitor CST.

A light-emitting element LE emits light according to a current supplied through a driving transistor DTR. The light-emitting element LE may be implemented as an inorganic light-emitting diode, an organic light-emitting diode, a micro-light-emitting diode, or a nano-light-emitting diode.

The light-emitting element LE may have a first electrode (e.g., an anode) connected to a source electrode of the driving transistor DTR, and may have a second electrode (e.g., a cathode) connected to a second power line ELVSL to which a low potential voltage (a second power supply voltage), which is lower than a high potential voltage (a first power supply voltage) of a first power line ELVDL, is supplied.

The driving transistor DTR adjusts a current flowing from the first power line ELVDL, to which the first power supply voltage is supplied, to the light-emitting element LE according to a voltage difference between a gate electrode and the source electrode. The driving transistor DTR may have the gate electrode connected to a first electrode of a first transistor STR1, the source electrode connected to the first electrode of the light-emitting element LE, and a drain electrode connected to the first power line ELVDL to which the first power supply voltage is applied.

The first transistor STR1 is turned on by a scan signal of a scan line SCL to connect a data line DTL to the gate electrode of the driving transistor DTR. The first transistor STR1 may have a gate electrode connected to the scan line SCL, the first electrode connected to the gate electrode of the driving transistor DTR, and a second electrode connected to the data line DTL.

A second transistor STR2 is turned on by a sensing signal of a sensing signal line SSL to connect an initialization voltage line VIL to the source electrode of the driving transistor DTR. The second transistor STR2 may have a gate electrode connected to the sensing signal line SSL, a first electrode connected to the initialization voltage line VIL, and a second electrode connected to the source electrode of the driving transistor DTR.

In one or more embodiments, the first electrode of each of the first and second transistors STR1 and STR2 may be a source electrode, and the second electrode may be a drain electrode. However, embodiments of the present specification are not limited thereto, and the opposite may also be the case.

The capacitor CST is formed between the gate electrode and the source electrode of the driving transistor DTR. The storage capacitor CST stores a difference voltage between a gate voltage and a source voltage of the driving transistor DTR.

The driving transistor DTR and the first and second transistors STR1 and STR2 may be formed as thin-film transistors. In addition, although the driving transistor DTR and the first and second switching transistors STR1 and STR2 are mainly described as N-type metal oxide semiconductor field effect transistors (MOSFETs) in FIG. 5, embodiments of the present specification are not limited thereto. That is, the driving transistor DTR and the first and second switching transistors STR1 and STR2 may also be P-type MOSFETs, or some of them may be N-type MOSFETs, and the other may be a P-type MOSFET.

Referring to FIG. 6, a light-emitting element LE of a pixel circuit unit PXC according to one or more embodiments may have a first electrode connected to a first electrode of a fourth transistor STR4 and to a second electrode of a sixth transistor STR6, and may have a second electrode connected to a second power line ELVSL. A parasitic capacitance Cel may be formed between the first electrode and the second electrode of the light-emitting element LE.

Each pixel PX includes a driving transistor DTR, switch elements, and a capacitor CST. The switch elements include first through sixth transistors STR1 through STR6.

The driving transistor DTR includes a gate electrode, a first electrode, and a second electrode. The driving transistor DTR controls a drain-source current (hereinafter, referred to as a “driving current”) flowing between the first electrode and the second electrode according to a data voltage applied to the gate electrode.

The capacitor CST is formed between the second electrode of the driving transistor DTR and a first power line ELVDL. The capacitor CST may have one electrode connected to the second electrode of the driving transistor DTR, and may have the other electrode connected to the first power line ELVDL.

When a first electrode of each of the first through sixth transistors STR1 through STR6 and the driving transistor DTR is a source electrode, a second electrode may be a drain electrode. Alternatively, if the first electrode of each of the first through sixth transistors STR1 through STR6 and the driving transistor DTR is a drain electrode, the second electrode may be a source electrode.

An active layer of each of the first through sixth transistors STR1 through STR6 and the driving transistor DTR may be made of any one of polysilicon, amorphous silicon, or an oxide semiconductor. When a semiconductor layer of each of the first through sixth transistors STR1 through STR6 and the driving transistor DTR is made of polysilicon, a process for forming the semiconductor layer may be a low-temperature polysilicon (LTPS) process.

In addition, although the first through sixth transistors STR1 through STR6 and the driving transistor DTR are mainly described as P-type MOSFETs in FIG. 6, embodiments of the present specification are not limited thereto, and they may also be formed as N-type MOSFETs.

Further, the first power supply voltage of the first power line ELVDL, a second power supply voltage of the second power line ELVSL, and a third power supply voltage of a third power line VIL may be set in consideration of characteristics of the driving transistor DTR and characteristics of the light-emitting element LE.

Referring to FIG. 7, a pixel circuit unit PXC according to one or more embodiments is different from that of the one or more embodiments corresponding to FIG. 6 in that a driving transistor DTR, a second transistor STR2, a fourth transistor STR4, a fifth transistor STR5, and a sixth transistor STR6 are formed as P-type MOSFETs, and a first transistor STR1 and a third transistor STR3 are formed as N-type MOSFETs.

An active layer of each of the driving transistor DTR, the second transistor STR2, the fourth transistor STR4, the fifth transistor STR5, and the sixth transistor STR6 formed as P-type MOSFETs may be made of polysilicon, and an active layer of each of the first transistor STR1 and the third transistor STR3 formed as N-type MOSFETs may be made of an oxide semiconductor.

The one or more embodiments corresponding to FIG. 7 is different from the one or more embodiments corresponding to FIG. 4 in that a gate electrode of the second transistor STR2 and a gate electrode of the fourth transistor STR4 are connected to a write scan line GWL and that a gate electrode of the first transistor STR1 is connected to a control scan line GCL. In FIG. 7, because the first transistor STR1 and the third transistor STR3 are formed as N-type MOSFETs, a scan signal of a gate-high voltage may be transmitted to the control scan line GCL and to an initialization scan line GIL. In contrast, because the second transistor STR2, the fourth transistor STR4, the fifth transistor STR5, and the sixth transistor STR6 are formed as P-type MOSFETs, a scan signal of a gate-low voltage may be transmitted to the write scan line GWL and an emission line EL.

It should be noted that the equivalent circuit diagrams of the pixels of the present specification described above are not limited to those illustrated in FIGS. 5 through 7. The equivalent circuit diagrams of the pixels may also be formed in other known circuit structures that can be employed by those skilled in the art, in addition to the embodiments illustrated in FIGS. 5 through 7.

The circuit-insulating layer CINO may be located on the pixel circuit units PXC. The circuit-insulating layer CINO may protect the pixel circuit units PXC, and may planarize a step difference of the pixel circuit units PXC. The circuit-insulating layer CINO may expose the pixel electrodes 111 so that the pixel electrodes 111 can be connected to the light-emitting element layer 120. The circuit-insulating layer CINO may include an inorganic insulating material, such as silicon oxide (SiOₓ), silicon nitride (SiNₓ), silicon oxynitride (SiOₓN_{y}), aluminum oxide (AlₓO_{y}), or aluminum nitride (AlN).

Each of the pixel electrodes 111 may be located on a corresponding pixel circuit unit PXC. Each of the pixel electrodes 111 may be an electrode exposed from the pixel circuit unit PXC. Each of the pixel electrodes 111 may be integrally formed with the pixel circuit unit PXC. Each of the pixel electrodes 111 may receive a pixel voltage or an anode voltage from the pixel circuit unit PXC. The pixel electrodes 111 may include a metal material, such as aluminum (Al).

Each of the contact electrodes 112 may be located on a corresponding pixel electrode 111. The contact electrodes 112 may include a metal material to bond the pixel electrodes 111 to the light-emitting elements LE. For example, the contact electrodes 112 may include at least any one of gold (Au), copper (Cu), aluminum (Al), or tin (Sn). Alternatively, the contact electrodes 112 may include a first layer including any one of gold (Au), copper (Cu), aluminum (Al), or tin (Sn), and may include a second layer including another one of gold (Au), copper (Cu), aluminum (Al), or tin (Sn). In a modified example, if the contact electrodes 112 and the pixel insulating layer CINO are omitted, the pixel electrodes 111 may include at least any one of gold (Au), copper (Cu), tin (Sn), or silver (Ag).

The common contact electrode 113 may be located in the first common voltage supply area CVA1 of the non-display area NDA. The common contact electrode 113 may be located on both sides of the display area DA. The common contact electrode 113 may be connected to any one of the first pads PD1 of the first pad portion PDA1 through a circuit unit formed in the non-display area NDA, and may receive a common voltage. The common contact electrode 113 may include the same material as the pixel electrodes 111. That is, the common contact electrode 113 and the pixel electrodes 111 may be formed in the same process.

Each of the first pads PD1 may be connected to a pad electrode CPD of a circuit board CB through a corresponding conductive connection member, such as a wire WR. That is, the first pads PD1, the wires WR, and the pad electrodes CPD of the circuit board CB may be connected one-to-one to each other.

The circuit board CB may be a flexible printed circuit board (FPCB), a printed circuit board (PCB), a flexible printed circuit (FPC), or a flexible film, such as a chip on film (COF).

The second pads of the second pad portion PDA2 (see FIG. 1) may be substantially the same as the first pads PD1 described with reference to FIGS. 4 and 5, and thus a description thereof will be omitted.

The light-emitting element layer 120 may include the light-emitting elements LE, a first insulating layer INS1, connection electrodes 125, a common connection electrode 127, a filler CINS, color conversion layers CCL2 and CCL3, a common electrode CME, and a second insulating layer INS2.

The light-emitting element layer 120 may include first light-emitting areas EA1, second light-emitting areas EA2, and third light-emitting areas EA3 corresponding to the light-emitting elements LE, respectively. The light-emitting elements LE may be located in the first light-emitting areas EA1, the second light-emitting areas EA2, and the third light-emitting areas EA3, respectively. An area that does not correspond to the light-emitting areas EA1 through EA3 in the display area DA may be referred to as a non-light-emitting area.

The light-emitting elements LE may be located on the contact electrodes 112 in the first light-emitting areas EA1, the second light-emitting areas EA2, and the third light-emitting areas EA3, respectively. The light-emitting elements LE may be vertical light-emitting diode elements extending in the third direction DR3. That is, a length of each of the light-emitting elements LE in the third direction DR3 may be greater than a length in a horizontal direction. The length in the horizontal direction refers to a length in the first direction DR1 and/or a length in the second direction DR2. For example, the length of each of the light-emitting elements LE in the third direction DR3 may be about μm to 5 μm.

The light-emitting elements LE may be micro-light-emitting diode elements. As illustrated in FIG. 10, each of the light-emitting elements LE may include a connection electrode 125, a first semiconductor layer SEM1, an electron-blocking layer EBL, an active layer MQW, a superlattice layer SLT, and a second semiconductor layer SEM2 in the third direction DR3. The connection electrode 125, the first semiconductor layer SEM1, the electron-blocking layer EBL, the active layer MQW, the superlattice layer SLT, the second semiconductor layer SEM2, and a third semiconductor layer SEM3 may be sequentially stacked in the third direction DR3.

As illustrated in FIG. 10, each of the light-emitting elements LE may be shaped like a cylinder, disk, or rod whose width is greater than its height. However, embodiments of the present specification are not limited thereto, and each of the light-emitting elements LE may also have various shapes including shapes, such as a rod, a wire, and a tube, polygonal prisms, such as a cube, a rectangular parallelepiped, and a hexagonal prism, and a shape extending in a direction and having a partially inclined outer surface.

The connection electrode 125 may be located on a contact electrode 112. The connection electrode 125 may adhere to the contact electrode 112 to transmit an emission signal to a corresponding light-emitting element LE. The light-emitting element LE may include at least one connection electrode 125. Although the light-emitting element LE includes one connection electrode 125 in FIG. 10, embodiments of the present specification are not limited thereto. In some cases, the light-emitting element LE may include a greater number of the connection electrodes 125, or the connection electrode 125 may be omitted. The following description of the light-emitting element LE may apply equally even if the number of the connection electrodes 125 is changed or if the light-emitting element LE further includes another structure.

When the light-emitting element LE is electrically connected to a pixel electrode in the display panel 100 according to one or more embodiments, the connection electrode 125 may reduce the resistance between the light-emitting element LE and the contact electrode. The connection electrode 125 may include a conductive metal. For example, the connection electrode 125 may include at least any one of gold (Au), copper (Cu), tin (Sn), titanium (Ti), aluminum (Al), or silver (Ag). For example, the connection electrode 125 may include a 9:1 alloy, an 8:2 alloy or a 7:3 alloy of gold and tin, or may include an alloy (SAC305) of copper, silver, and tin.

The first semiconductor layer SEM1 may be located on the connection electrode 125. The first semiconductor layer SEM1 may be a p-type semiconductor, and may include a semiconductor material having a chemical formula of AlₓGa_{y}In_{1-x-y}N (0≤x≤1, 0≤y≤1, 0≤x+y≤1). For example, the first semiconductor layer SEM1 may be any one or more of p-type doped AlGaInN, GaN, AlGaN, InGaN, AlN, or InN. The first semiconductor layer SEM1 may be doped with a p-type dopant, and the p-type dopant may be Mg, Zn, Ca, Se, Ba, or the like. For example, the first semiconductor layer SEM1 may be p-GaN doped with p-type Mg. A thickness of the first semiconductor layer SEM1 may be in the range of, but not limited to, about 30 nm to about 200 nm.

The electron-blocking layer EBL may be located on the first semiconductor layer SEM1. The electron-blocking layer EBL may be a layer for suppressing or preventing too many electrons from flowing into the active layer MQW. For example, the electron-blocking layer EBL may be p-AlGaN doped with p-type Mg. A thickness of the electron-blocking layer EBL may be in the range of, but not limited to, about 10 nm to about 50 nm. The electron-blocking layer EBL may also be omitted.

The active layer MQW may be located on the electron-blocking layer EBL. The active layer MQW may emit light through combination of electron-hole pairs according to electrical signals received through the first semiconductor layer SEM1 and the second semiconductor layer SEM2. The active layer MQW may emit the first light, (e.g., light in the blue wavelength band) or the second light (e.g., light in the green wavelength band).

The active layer MQW may include a material having a single or multiple quantum well structure. When the active layer MQW includes a material having a multiple quantum well structure, it may have a structure in which a plurality of well layers and a plurality of barrier layers are alternately stacked. Here, the well layers may be made of InGaN, and the barrier layers may be made of GaN or AlGaN, but embodiments of the present specification are not limited thereto. The well layers may have a thickness of about 1 nm to about 4 nm, and the barrier layers may have a thickness of about 3 nm to about 10 nm.

Alternatively, the active layer MQW may have a structure in which a semiconductor material having a large band gap energy and a semiconductor material having a small band gap energy are alternately stacked or may include different Group III to Group V semiconductor materials depending on the wavelength band of light that it emits. Light emitted from the active layer MQW is not limited to the first light. In some cases, the second light (light in the green wavelength band) or the third light (light in the red wavelength band) may be emitted. In one or more embodiments, if indium is included among the semiconductor materials included in the active layer MQW, the color of light emitted may vary according to the indium content. For example, light in the blue wavelength band may be emitted if the indium content is about 15%, light in the green wavelength band may be emitted if the indium content is about 25%, and light in the green wavelength band may be emitted if the indium content is about 35% or more.

The superlattice layer SLT may be located on the active layer MQW. The superlattice layer SLT may be a layer for relieving stress between the second semiconductor layer SEM2 and the active layer MQW. For example, the superlattice layer SLT may be made of InGaN or GaN. A thickness of the superlattice layer SLT may be about 50 nm to about 200 nm. The superlattice layer SLT may also be omitted.

The second semiconductor layer SEM2 may be located on the superlattice layer SLT. The second semiconductor layer SEM2 may be an n-type semiconductor. The second semiconductor layer SEM2 may include a semiconductor material having a chemical formula of AlₓGa_{y}In_{1-x-y}N (0≤x≤1, 0≤y≤1, 0≤x+y≤1). For example, the second semiconductor layer SEM2 may be any one or more of n-type doped AlGalnN, GaN, AlGaN, InGaN, AlN, or InN. The second semiconductor layer SEM2 may be doped with an n-type dopant, and the n-type dopant may be Si, Ge, Sn, or the like. For example, the second semiconductor layer SEM2 may be n-GaN doped with n-type Si. A thickness of the second semiconductor layer SEM2 may be in the range of, but not limited to, about 2 μm to about 4 μm.

Each of the first light-emitting areas EA1 may include a light transmission layer TPL on a light-emitting element LE. The light transmission layer TPL may contact an upper surface of the light-emitting element LE.

The light transmission layer TPL may include the third semiconductor layer SEM3, and may transmit the first light emitted from the light-emitting element LE as it is. Therefore, each of the first light-emitting areas EA1 may emit the first light.

The third semiconductor layer SEM3 may be located on the second semiconductor layer SEM2. The third semiconductor layer SEM3 may be an undoped semiconductor. The third semiconductor layer SEM3 may include the same material as the second semiconductor layer SEM2, but may be a material not doped with an n-type or p-type dopant. In one or more embodiments, the third semiconductor layer SEM3 may be, but is not limited to, at least any one of undoped InAlGaN, GaN, AlGaN, InGaN, AlN, or InN. The third semiconductor layer SEM3 may include a plurality of pores OP.

In the description above, a configuration in which a common electrode is commonly located in a plurality of pixels has been shown. However, embodiments of the present specification are not limited thereto, and a configuration in which a separate common connection electrode is located in each of the pixels may also be considered. Even in this case, the configuration of the light-emitting element LE of the light-emitting area and the common electrode in each pixel are similar to those described with reference to FIGS. 4 and 8 through 10, and thus a detailed description thereof will be omitted.

Referring to FIG. 11, in one or more embodiments, the light-emitting element LE may not include the light transmission layer TPL in each of the first light-emitting areas EA1. When the light-emitting element LE does not include the light transmission layer TPL, the second insulating layer INS2 may contact the upper surface of the light-emitting element LE, that is, the second semiconductor layer SEM2.

In each of the second light-emitting areas EA2 and the third light-emitting areas EA3, the color conversion layer CCL2 or CCL3 may be located on the light-emitting element LE. The color conversion layer CCL2 or CCL3 may contact the upper surface of the light-emitting element LE.

Each of the color conversion layers CCL2 and CCL3 may include the third semiconductor layer SEM3 and wavelength conversion particles WCP2 or WCP3. The third semiconductor layer SEM3 may include a plurality of pores OP that accommodate the wavelength conversion particles WCP2 or WCP3.

Second wavelength conversion particles WCP2 may convert the first light emitted from the light-emitting element LE into the second light. For example, the second wavelength conversion particles WCP2 may convert light in the blue wavelength band into light in the green wavelength band. Therefore, the second light-emitting areas EA2 may emit the second light.

Third wavelength conversion particles WCP3 may convert the first light emitted from the light-emitting element LE into the third light. For example, the third wavelength conversion particles WCP3 may convert light in the blue wavelength band into light in the red wavelength band. Therefore, the third light-emitting areas EA3 may emit the third light.

The wavelength conversion particles WCP1 and WCP2 may be quantum dots, quantum rods, a fluorescent material, or a phosphorescent material. The quantum dots may include Group IV nanocrystals, Group II-VI compound nanocrystals, Group III-V compound nanocrystals, Group IV-VI nanocrystals, or a combination thereof.

Each quantum dot may include a core, and a shell over-coating the core. The core may be, but is not limited to, at least one of, for example, CdS, CdSe, CdTe, ZnS, ZnSe, ZnTe, GaN, GaP, GaAs, GaSb, AlN, AIP, AIAs, AISb, InP, InAs, InSb, SiC, Ca, Se, In, P, Fe, Pt, Ni, Co, Al, Ag, Au, Cu, FePt, Fe₂O₃, Fe₃O₄, Si, or Ge. The shell may include, but not limited to, at least one of, for example, ZnS, ZnSe, ZnTe, CdS, CdSe, CdTe, HgS, HgSe, HgTe, AlN, AIP, AIAs, AISb, GaN, GaP, GaAs, GaSb, GaSe, InN, InP, InAs, InSb, TIN, TIP, TIAs, TISb, PbS, PbSe, or PbTe.

The common connection electrode 127 may be located in the first common voltage supply area CVA1 of the non-display area NDA. The common connection electrode 127 may be located on a surface of a first common electrode CME1. The common connection electrode 127 may transmit a common voltage signal from the common contact electrode 113 to the light-emitting elements LE. The common connection electrode 127 may be made of the same material as the connection electrodes 125. The common connection electrode 127 may be thick in the third direction DR3 so that it can be connected to the common contact electrode 113.

The light-emitting elements LE described above may receive pixel voltages or anode voltages of the pixel electrodes 111 through the connection electrodes 125, and may receive a common voltage through the common electrode CME. Each of the light-emitting elements LE may emit light with a luminance (e.g., predetermined luminance) according to a voltage difference between the pixel voltage and the common voltage.

The first insulating layer INS1 may surround the first semiconductor layer SEM1, the electron-blocking layer EBL, the active layer MQW, and the superlattice layer SLT of each light-emitting element LE. The first insulating layer INS1 may expose at least a portion of side surfaces of the second semiconductor layer SEM2.

In addition, the first insulating layer INS1 may cover at least a portion of a surface of each light-emitting element LE. The first insulating layer INS1 may cover at least a portion of a surface of the first semiconductor layer SEM1. The first insulating layer INS1 has, or defines, a first opening OPE1 on the surface of each light-emitting element LE. The surface of each light-emitting element LE is exposed through the first opening OPE1.

A width of the first opening OPE1 is smaller than that of each light-emitting element LE. The first opening OPE1 may be circular in plan view. However, embodiments of the present specification are not limited thereto, and the planar shape of the first opening OPE1 may also follow the planar shape of each light-emitting element LE. For example, the planar shape of the first opening OPE1 may be a polygonal shape, such as a triangle, a quadrilateral, or a pentagon.

The connection electrode 125 is located in the first opening OPE1. The connection electrode 125 contacts the first semiconductor layer SEM1. A width W2 of the connection electrode 125 is smaller than a width W1 of the first opening OPE1.

The first insulating layer INS1 may include an inorganic insulating material, such as silicon oxide (SiOₓ), silicon nitride (SiNₓ), silicon oxynitride (SiOₓN_{y}), aluminum oxide (AlₓO_{y}), or aluminum nitride (AlN). A thickness of the first insulating layer INS1 may be, but is not limited to, about 0.1 μm. The first insulating layer INS1 may insulate the first semiconductor layer SEM1, the electron-blocking layer EBL, the active layer MQW, and the superlattice layer SLT of each light-emitting element LE from other layers.

The common electrode CME may be located on the semiconductor circuit board 110. For example, the common electrode CME may be located on a surface of the semiconductor circuit board 110 on which the light-emitting elements LE are formed, and may be entirely located in the display area DA and the non-display area NDA. The common electrode CME may overlap the common connection electrode 127 in the non-display area NDA, and may contact a surface of the common connection electrode 127.

The common electrode CME may be directly located on the surface of the semiconductor circuit board 110, and may be directly located on side surfaces of the light-emitting elements LE. The common electrode CME may directly contact the side surfaces of the second semiconductor layers SEM2 among the side surfaces of the light-emitting elements LE. The common electrode CME may be a common layer surrounding the light-emitting elements LE, and connecting the light-emitting elements LE in common. Because the second semiconductor layer SEM2 having conductivity is a patterned structure in each of the light-emitting elements LE, the common electrode CME may directly contact the side surfaces of the second semiconductor layer SEM2 of each light-emitting element LE so that a common voltage can be applied to each light-emitting element LE.

Because the common electrode CME surrounds the side surfaces of the second semiconductor layer SEM2, it may reflect light leaking through the side surfaces after being emitted from the active layer MQW of each light-emitting element LE. The common electrode CME reflects light to travel in left and right lateral directions instead of an upward direction among the light emitted from the light-emitting elements LE. That is, the common electrode CME reflects light to each light-emitting area EA1, EA2, or EA3, thereby reducing or preventing the likelihood of light leaking to adjacent light-emitting areas EA1 through EA3 and causing color mixing.

The common electrode CME may include a material having low resistance because the common electrode CME is located on the entire semiconductor circuit board 110, and receives a common voltage. In addition, the common electrode CME may include a material having high reflectivity to easily reflect light. For example, the common electrode CME may include a metal material having high reflectivity, such as aluminum (Al) or silver (Ag).

The common electrode CME may include the first common electrode CME1 and a second common electrode CME2. The common electrode CME is the second electrode (e.g., the cathode) of each light-emitting element LE.

The first common electrode CME1 may include a first portion CME1-1 surrounding the side surfaces of the light-emitting elements LE, and a second portion CME1-2 extending from the first portion CME1-1 and covering the semiconductor circuit board 110.

The second portion CME1-2 of the first common electrode CME1 covers the non-light-emitting area.

The first portion CME1-1 of the first common electrode CME1 reflects light traveling in all lateral directions instead of the upward direction, among the light emitted from the light-emitting elements LE. The first portion CME1-1 of the first common electrode CME1 may be located in the display area DA. The first portion CME1-1 of the first common electrode CME1 may overlap the first light-emitting areas EA1, the second light-emitting areas EA2, and the third light-emitting areas EA3 in the display area DA.

The first portion CME1-1 of the first common electrode CME1 may include a reflective portion CME1-11 and an electrode portion CME1-12.

The reflective portion CME1-11 may be directly located on the first insulating layer INS1, and may be located on the side surfaces and one surface of the first insulating layer INS1. The first portion CME1-1 of the first common electrode CME1 may be spaced apart from the light-emitting elements LE.

The reflective portion CME1-11 includes a second opening OPE2 on a surface of each light-emitting element LE. A width W3 of the second opening OPE2 may be equal to or greater than the width W1 of the first opening OPE1. The width W3 of the second opening OPE2 is greater than the width W2 of the connection electrode 125.

The electrode portion CME1-12 may extend from the reflective portion CME1-11 to directly lie on the second semiconductor layer SEM2 of each light-emitting element LE, and may be located on the side surfaces of the second semiconductor layer SEM2. That is, the common electrode CE contacts the side surfaces of the light-emitting elements LE.

The second common electrode CME2 may include a third portion CME2-1 surrounding side surfaces of the light transmission layer TPL and the color conversion layers CCL2 and CCL3, and may include a fourth portion CME2-2 extending from the third portion CME2-1 and covering the semiconductor circuit board 110.

The fourth portion CME2-2 of the second common electrode CME2 covers the non-light-emitting area.

The fourth portion CME2-2 of the second common electrode CME2 is located on the second portion CME1-2 of the first common electrode CME1, and contacts the second portion CME1-2.

The third portion CME2-1 of the second common electrode CME2 reflects light traveling in all lateral directions instead of the upward direction among the light emitted from the light-emitting elements LE. The third portion CME2-1 of the second common electrode CME2 may be located in the display area DA. The third portion CME2-1 of the second common electrode CME2 may overlap the first light-emitting areas EA1, the second light-emitting areas EA2, and the third light-emitting areas EA3 in the display area DA.

The first portion CME1-1 of the first common electrode CME1 and the third portion CME2-1 of the second common electrode CME2 overlap each other in the third direction DR3.

The second portion CME1-2 of the first common electrode CME1 and the fourth portion CME2-2 of the second common electrode CME2 overlap each other in the third direction DR3. The second portion CME1-2 of the first common electrode CME1 and the fourth portion CME2-2 of the second common electrode CME2 contact each other.

The light-emitting elements LE described above may receive the pixel voltages or anode voltages of the pixel electrodes 111 through the connection electrodes 125, and may receive the common voltage through the common electrode CME. Each of the light-emitting elements LE may emit light with a luminance (e.g., predetermined luminance) according to a voltage difference between the pixel voltage and the common voltage.

The filler CINS may be located between the common connection electrode 127 and the light-emitting elements LE. The filler CINS may bond the semiconductor circuit board 110 to the light-emitting element layer 120. The filler CINS may fill a space between the semiconductor circuit board 110 and the light-emitting element layer 120. The filler CINS may include an insulating material, for example, an organic insulating material.

The second insulating layer INS2 may be located on the upper surfaces of the light-emitting elements LE and on the common electrode CME. The second insulating layer INS2 may completely cover the light-emitting elements LE and the common electrode CME. The second insulating layer INS2 may be made of the same material as the first insulating layer INS1. The second insulating layer INS2 may include an inorganic insulating material, such as silicon oxide (SiOₓ), silicon nitride (SiNₓ), silicon oxynitride (SiOₓN_{y}), aluminum oxide (AlₓO_{y}), or aluminum nitride (AlN).

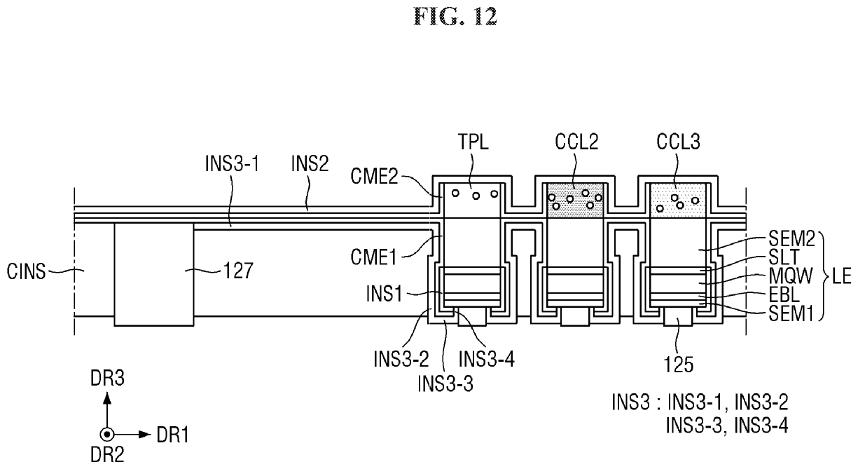

FIG. 12 is a view of an example of a light-emitting element layer according to one or more embodiments of the present disclosure.

Referring to FIG. 12, the current one or more embodiments are different from the one or more embodiments described above with reference to FIGS. 8 through 10 in that a third insulating layer INS3 is formed to fill spaces between connection electrodes 125 and a first common electrode CME1. Therefore, a description of the same elements will be given briefly or omitted, and differences will be described in detail below.

The third insulating layer INS3 may be formed on a semiconductor circuit board 110 to cover the first common electrode CME1. The third insulating layer INS3 may be entirely located in a display area DA where light-emitting elements LE are not located. The third insulating layer INS3 may surround not only a first semiconductor layer SEM1, an electron-blocking layer EBL, an active layer MQW, and a superlattice layer SLT of each light-emitting element LE, but also a second semiconductor layer SEM2. The third insulating layer INS3 includes a fifth portion INS3-1 not overlapping light-emitting areas EA1 through EA3, a sixth portion INS3-2 surrounding side surfaces of the light-emitting elements LE, a seventh portion INS3-3 covering a surface of each light-emitting element LE, and an eighth portion INS3-4 filling the spaces between the first common electrode CME1 and the connection electrodes 125.

The seventh portion INS3-3 may include, or define, second openings OPE2. Because each of the second openings OPE2 is similar to that described with reference to FIG. 10, a redundant description thereof is omitted.

The connection electrodes 125 are located in the second openings OPE2, and a first insulating layer INS1 and the first common electrode CME1 are spaced apart from the connection electrodes 125. The first insulating layer INS1 and the first common electrode CME1 do not directly contact the connection electrodes 125.

The eighth portion INS3-4 is formed by filling the spaces between the first insulating layer INS1 and the connection electrodes 125, and between the first common electrode CME1 and the connection electrodes 125, with the third insulating layer INS3. Therefore, the first common electrode CME1 may be insulated from the connection electrodes 125 by the third insulating layer INS3.

The third insulating layer INS3 may be made of the same material as the first insulating layer INS1 and a second insulating layer INS2. The third insulating layer INS3 may include an inorganic insulating material, such as silicon oxide (SiOₓ), silicon nitride (SiNₓ), silicon oxynitride (SiOₓN_{y}), aluminum oxide (AlₓO_{y}), or aluminum nitride (AlN).

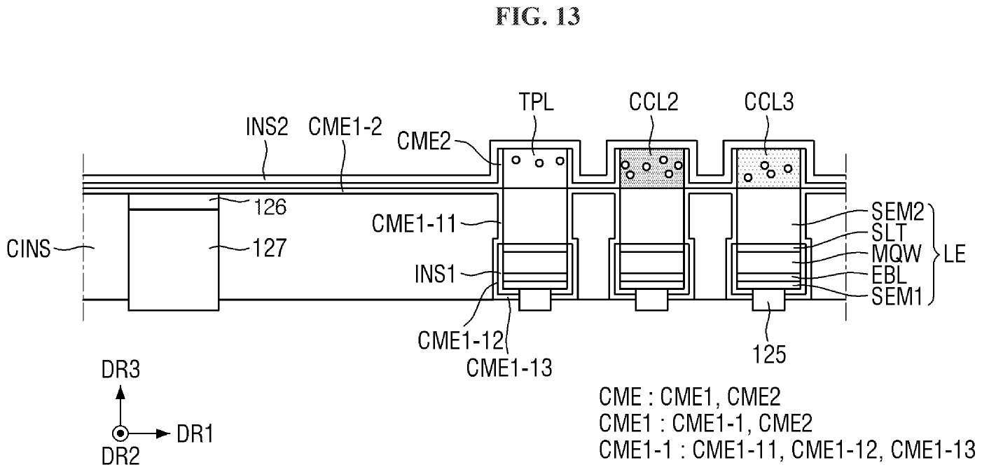

FIG. 13 is a view of an example of a light-emitting element layer according to one or more embodiments of the present disclosure.

Referring to FIG. 13, the current one or more embodiments are different from the one or more embodiments described above with reference to FIGS. 8 through 10 in that connection electrodes 125 and a first common electrode CME1 are formed to contact each other. Therefore, a description of the same elements will be given briefly or omitted, and differences will be described in detail below.

The first common electrode CME1 may be formed to directly contact side surfaces of a connection electrode 125 on a surface of each light-emitting element LE.

In this case, one side of the first common electrode CME1 in contact with the connection electrode 125 may be oxidized.

Because one side of the first common electrode CME1 in contact with the connection electrodes 125 is exposed to air, it may be naturally oxidized, and thus an oxide layer of about 1 nm to about 2 nm may be formed on a surface thereof. Alternatively, an oxide layer may be formed by heating that portion.

The oxide layer thus formed serves as an insulating layer that insulates the first common electrode CME1 from the connection electrodes 125.

In addition, a common connection electrode 127 may further include an ohmic contact layer 126 on a surface contacting the first common electrode CME1.

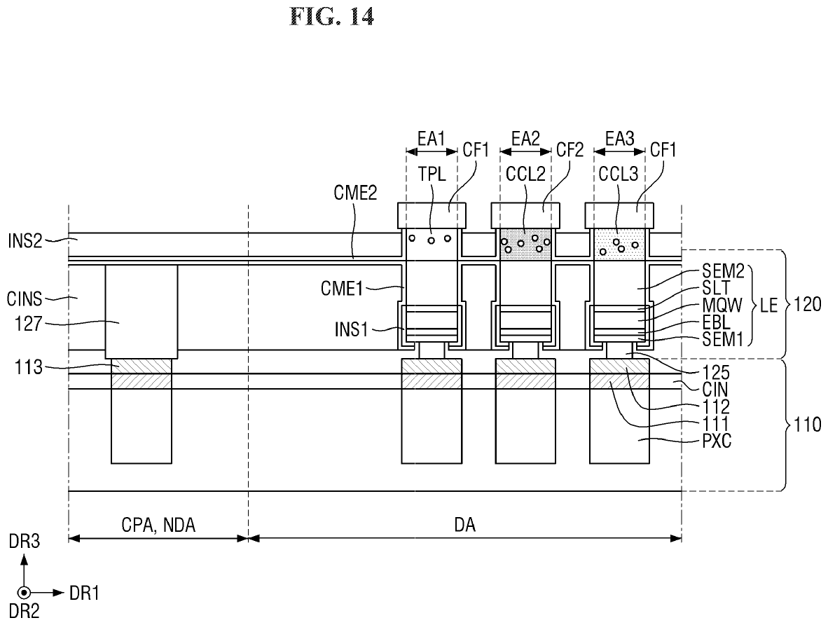

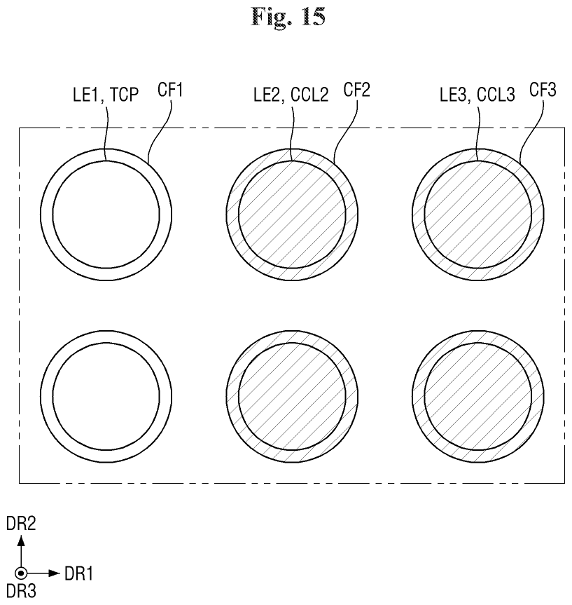

FIG. 14 is a cross-sectional view of an example of a display panel according to one or more embodiments, taken along the line A-A′ of FIG. 2. FIG. 15 is a plan view illustrating an example of color filters and light-emitting elements of FIG. 14.

Referring to FIG. 14, the current one or more embodiments are different from the one or more embodiments described above with reference to FIG. 4 in that color filters CF1 through CF3 are formed on color conversion layers CCL2 and CCL3, and on a light transmission layer TPL, of light-emitting elements LE. Therefore, a description of the same elements will be given briefly or omitted, and differences will be described in detail below.

The color filters CF1 through CF3 may be located on the color conversion layers CCL2 and CCL3 and the light transmission layer TPL.

The color filters CF1 through CF3 may include a first color filter CF1 overlapping a first light-emitting area EA1, a second color filter CF2 overlapping a second light-emitting area EA2, and a third color filter CF3 overlapping a third light-emitting area EA3.

The first color filter CF1 may be located on the light transmission layer TPL, and a lower surface of the first color filter CF1 may directly contact an upper surface of the light transmission layer TPL. The first color filter CF1 may completely cover the upper surface of the light transmission layer TPL.

The light transmission layer TPL described above may transmit first light emitted from a light-emitting element LE as it is. The first color filter CF1 transmits only the first light. For example, the first color filter CF1 may transmit light in a blue wavelength band, and may absorb, reduce, or block light in other wavelength bands, such as green and red wavelength bands.

The second color filter CF2 is located on a second color conversion layer CCL2. A lower surface of the second color filter CF2 may directly contact an upper surface of the second color conversion layer CCL2. The second color filter CF2 may completely cover the upper surface of the second color conversion layer CCL2.

The second color conversion layer CCL2 may convert the first light emitted from a light-emitting element LE into second light. The second color filter CF2 may transmit the second light into which the first light has been converted by the second color conversion layer CCL2, and may absorb, reduce, or block some first light that has not been converted by the second color conversion layer CCL2. For example, the second color filter CF2 may transmit light in the green wavelength band and absorb or block light in other wavelength bands, such as the blue and green wavelength bands.

The third color filter CF3 is located on a third color conversion layer CCL3. A lower surface of the third color filter CF3 may directly contact an upper surface of the third color conversion layer CCL3. The third color filter CF3 may completely cover the upper surface of the third color conversion layer CCL3.

The third color conversion layer CCL3 may convert the first light emitted from a light-emitting element LE into third light. The third color filter CF3 may transmit the third light into which the first light has been converted by the third color conversion layer CCL3, and may absorb, reduce, or block some first light that has not been converted by the third color conversion layer CCL3. For example, the third color filter CF3 may transmit light in the red wavelength band, and may absorb, reduce, or block light in other wavelength bands, such as the blue and green wavelength bands.

Accordingly, the light emitted from the light-emitting elements LE may be output as the first light from the first light-emitting area EA1, as the second light from the second light-emitting area EA2, and as the third light from the third light-emitting area EA3, thereby realizing full color.

As described above, according to a display device according to embodiments, in a display panel having a color adjustment layer using a third semiconductor layer, a common electrode surrounding side surfaces of light-emitting elements and color conversion layers reduces or prevents color mixing of light, thereby improving color gamut.

A process of manufacturing a display device 10 according to one or more embodiments will now be described with reference to other drawings.

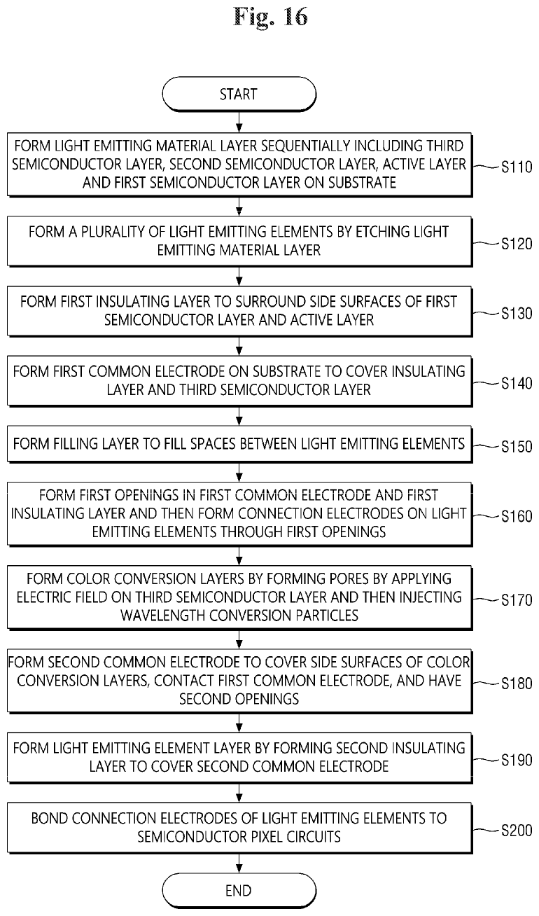

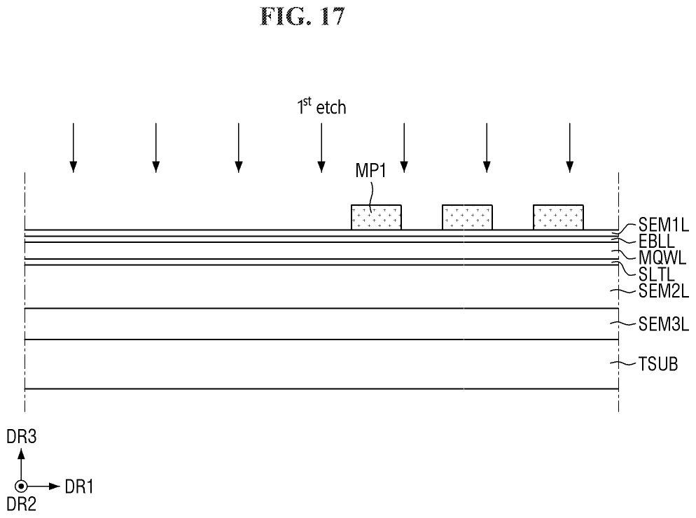

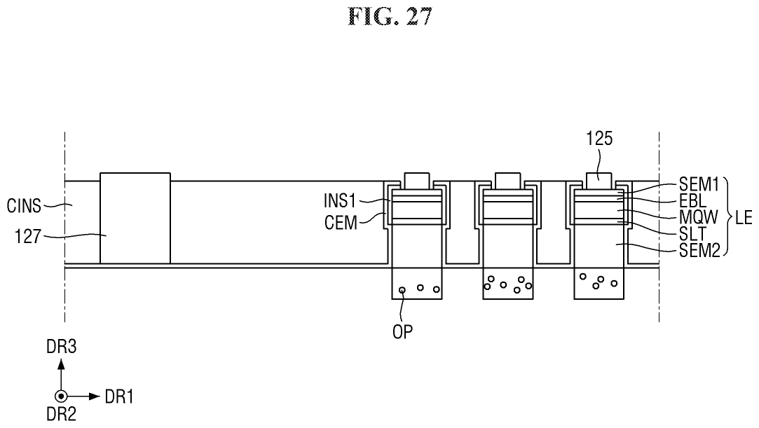

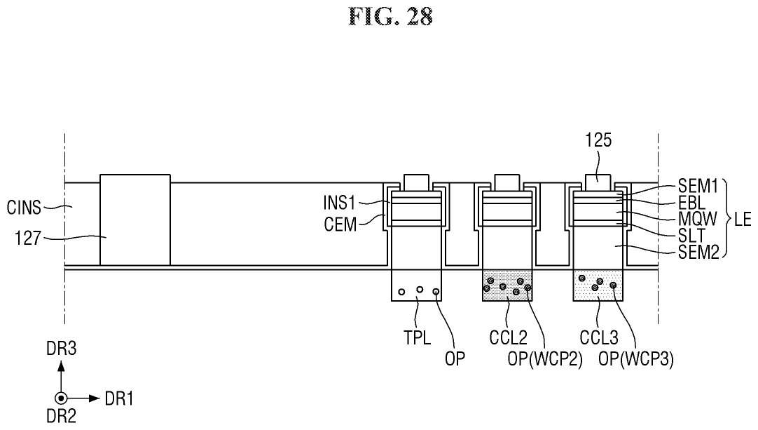

FIG. 16 is a flowchart illustrating a method of manufacturing a display panel according to one or more embodiments. FIGS. 17 through 32 are cross-sectional views illustrating the method of manufacturing the display panel according to one or more embodiments.

FIGS. 17 through 32 are cross-sectional views respectively illustrating structures according to the formation order of each layer of a display panel 100 of a display device 10. FIGS. 17 through 32 may each correspond to the cross-sectional view of FIG. 4. The method of manufacturing the display panel illustrated in FIGS. 17 through 32 will be described below in connection with FIG. 16.

Referring to FIG. 16, a plurality of semiconductor material layers SEM3L, SEM2L, SLTL, MQWL, EBLL, and SEM1L are formed on a target substrate TSUB (operation S110 in FIG. 16).

First, the target substrate TSUB is prepared. The target substrate TSUB may be a sapphire substrate (Al₂O₃) or a silicon wafer including silicon. However, embodiments of the present specification are not limited thereto. A case where the target substrate TSUB is a sapphire substrate will be described as an example.

The semiconductor material layers SEM3L, SEM2L, SLTL, MQWL, EBLL, and SEM1L are formed on the target substrate TSUB. A plurality of semiconductor material layers grown by an epitaxial method may be formed by growing seed crystals. Here, the semiconductor material layers may be formed by electron beam deposition, physical vapor deposition (PVD), chemical vapor deposition (CVD), plasma laser deposition (PLD), dual-type thermal evaporation, sputtering, or metal organic chemical vapor deposition (MOCVD). For example, the semiconductor material layers may be formed by MOCVD, but embodiments of the present specification are not limited thereto.

A precursor material for forming the semiconductor material layers is not particularly limited within a range of materials that can be generally selected to form a target material. For example, the precursor material may be a metal precursor including an alkyl group, such as a methyl group or an ethyl group. For example, the precursor material may be, but is not limited to, a compound, such as trimethyl gallium (Ga(CH₃)₃), trimethyl aluminum (Al(CH₃)₃), or triethyl phosphate (C₂H₅)₃PO₄.

For example, a third semiconductor material layer SEM3L is formed on the target substrate TSUB. For example, the third semiconductor material layer SEM3L may include an undoped semiconductor, and may be a material not doped with an n-type or p-type. In one or more embodiments, the third semiconductor material layer SEM3L may be, but is not limited to, at least any one of undoped InAlGaN, GaN, AlGaN, InGaN, AlN, or InN.

A second semiconductor material layer SEM2L, a superlattice material layer SLTL, an active material layer MQWL, an electron-blocking material layer EBLL, and a first semiconductor material layer SEM1L are sequentially formed on the third semiconductor material layer SEM3L using the above-described methods. The third semiconductor material layer SEM3L may be formed to a thickness of about 2 μm to about 3 μm, the second semiconductor material layer SEM2L may be formed to a thickness of about 2 μm to amount 4 μm, and the superlattice material layer SLTL may be formed to a thickness of about 50 nm to about 200 nm. The active material layer MQWL may include a quantum well and a barrier. The quantum well may be formed to a thickness of about 1 nm to about 4 nm, and the barrier may be formed to a thickness of about 3 nm to about 10 nm. The electron-blocking material layer EBLL may be formed to a thickness of about 10 nm to about 50 nm, and the first semiconductor material layer SEM1L may be formed to a thickness of about 30 nm to about 200 nm. However, these thicknesses are only an example, and embodiments of the present specification are not limited thereto.

Next, the second semiconductor material layer SEM2L, the superlattice material layer SLTL, the active material layer MQWL, the electron-blocking material layer EBLL, and the first semiconductor material layer SEM1L are etched to form a plurality of light-emitting elements LE (operation S120 in FIG. 16).

For example, a plurality of first mask patterns MP1 are formed on the first semiconductor material layer SEM1L. The first mask patterns MP1 may be a hard mask including an inorganic material or a photoresist mask including an organic material. The first mask patterns MP1 reduces or prevent the likelihood of the semiconductor material layers SEM3L, SEM2L, SLTL, MQWL, EBLL, and SEM1L thereunder being etched. Next, a plurality of light-emitting elements LE are formed by partially etching (first etching) the semiconductor material layers SEM3L, SEM2L, SLTL, MQWL, EBLL, and SEM1L using the first mask patterns MP1 as a mask.

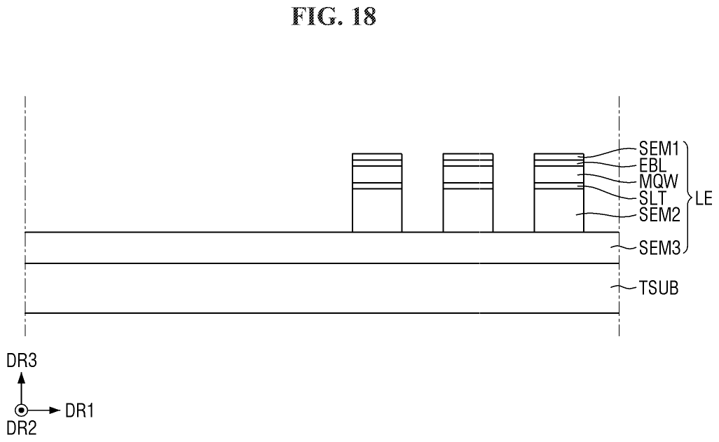

As illustrated in FIG. 18, portions of the semiconductor material layers SEM3L, SEM2L, SLTL, MQWL, EBLL, and SEM1L that do not overlap the first mask patterns MP1 may be etched and removed from the target substrate TSUB, and unetched portions that overlap the first mask patterns MP1 may be formed into the light-emitting elements LE.

The semiconductor material layers SEM3L, SEM2L, SLTL, MQWL, EBLL, and SEM1L may be etched by a conventional method. For example, the semiconductor material layers SEM3L, SEM2L, SLTL, MQWL, EBLL, and SEM1L may be etched by dry etching, wet etching, reactive ion etching (RIE), deep reactive ion etching (DRIE), or inductively coupled plasma reactive ion etching (ICP-RIE). Dry etching may allow anisotropic etching and may be suitable for vertical etching. When the above-described etching methods are used, an etchant may be, but is not limited to, Cl₂ or O₂.

The semiconductor material layers SEM3L, SEM2L, SLTL, MQWL, EBLL, and SEM1L overlapping the first mask patterns MP1 are formed into the light-emitting elements LE without being etched. Therefore, each of the light-emitting elements LE includes a third semiconductor layer SEM3, a second semiconductor layer SEM2, a superlattice layer SLT, an active layer MQW, an electron-blocking layer EBL, and a first semiconductor layer SEM1.

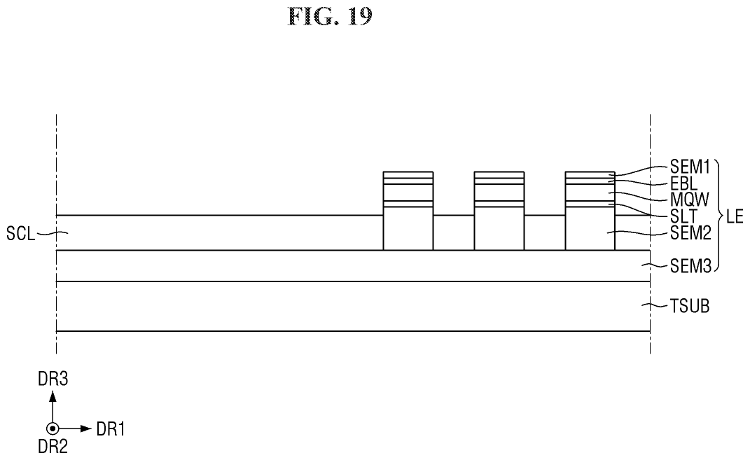

Referring to FIGS. 19 through 21, a first insulating layer is formed to surround side surfaces of the superlattice layer SLT, the active layer MQW, the electron-blocking layer EBL, and the first semiconductor layer SEM1 (operation S130 in FIG. 16).

First, referring to FIG. 19, a sacrificial layer SCL is formed between the light-emitting elements LE. The sacrificial layer SCL is formed to a height at which it covers at least a portion of the second semiconductor layer SEM2 but is not higher than the active layer MQW. The sacrificial layer SCL may be an organic layer.

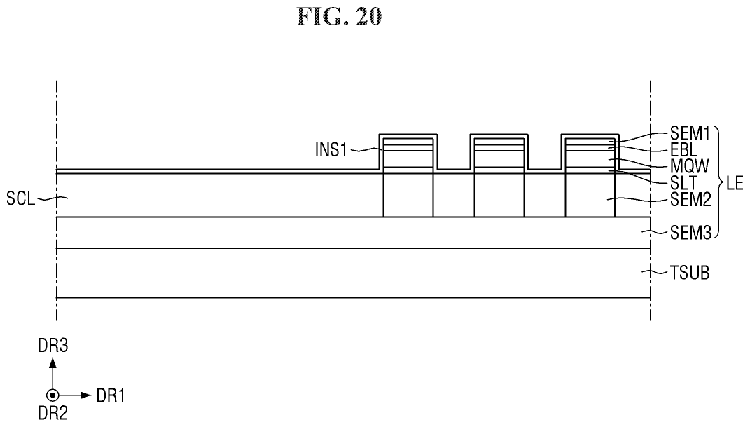

Referring to FIG. 20, an insulating material layer INS1L is coated on the target substrate TSUB on which the sacrificial layer SCL is formed. The insulating material layer INS1L may be entirely stacked on upper and side surfaces of the light-emitting elements LE and an upper surface of the sacrificial layer SCL. The insulating material layer INS1L may use an inorganic insulating material, such as silicon oxide, silicon nitride, or silicon oxynitride.

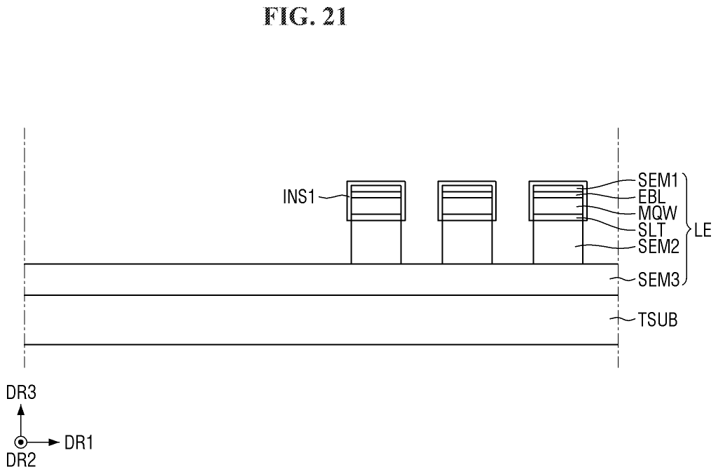

Next, referring to FIG. 21, the insulating material layer INS1L is partially etched away to leave only a first insulating layer INS1 covering the light-emitting elements LE. The etching process may be performed using one of the above-described etching methods. Then, the sacrificial layer SCL is removed from the target substrate TSUB. The sacrificial layer SCL may be removed by anisotropic etching.

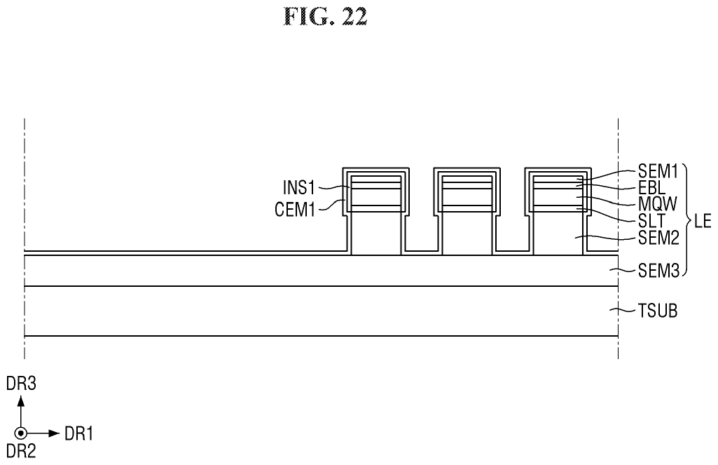

Next, referring to FIG. 22, a first common electrode CME1 is formed on the target substrate TSUB to cover the first insulating layer INS1 and the third semiconductor layer SEM3 (operation S140 in FIG. 16).

A common connection electrode material layer is stacked on the target substrate TSUB, and then is etched to form connection electrodes 125 on the light-emitting elements LE exposed by the first insulating layer INS1. The connection electrodes 125 may be directly formed on upper surfaces of the first semiconductor layers SEM1 of the light-emitting elements LE. In addition, a common connection electrode 127 is formed on the first common electrode CME1 at an edge of the target substrate TSUB. The common connection electrode 127 may be directly formed on a surface of the first common electrode CME1.

The connection electrodes 125 and the common connection electrode 127 may include a transparent conductive material. The connection electrodes 125 and the common connection electrode 127 may be made of a transparent conductive oxide (TCO), such as indium tin oxide (ITO) or indium zinc oxide (IZO).

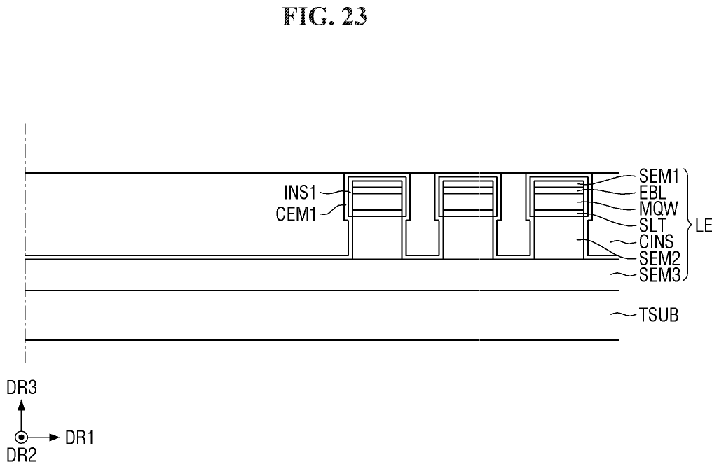

Referring to FIG. 23, spaces between the light-emitting elements LE on the target substrate TSUB are filled with a filler CINS (operation S150 in FIG. 16). The filler CINS may be referred to as a planarization layer because it planarizes heights of the spaces between the light-emitting elements LE. The filler CINS may include an insulating material, for example, an organic insulating material.

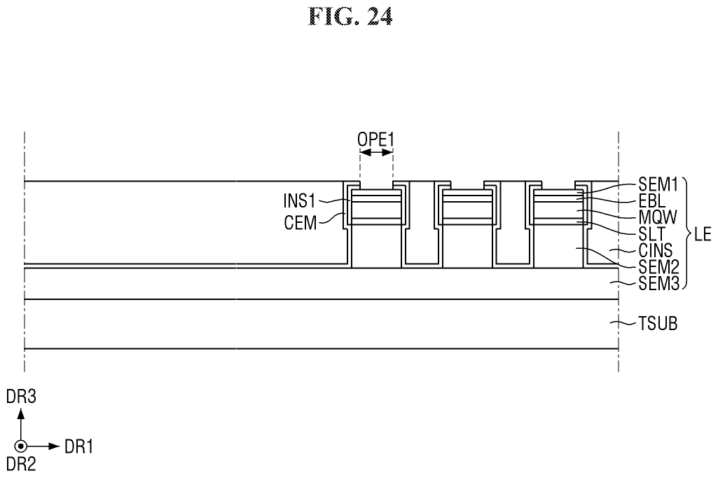

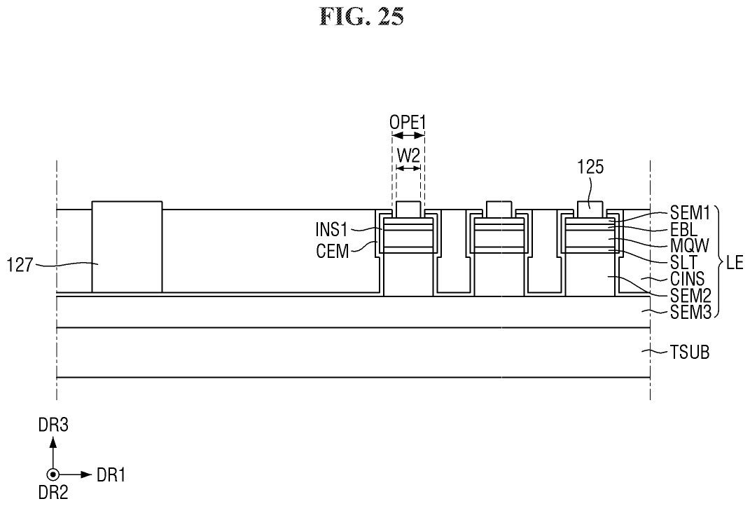

Referring to FIGS. 24 and 25, first openings OPE1 are formed in the first common electrode CME1 and the first insulating layer INS1. The connection electrodes 125 are formed on the light-emitting elements LE through the first openings OPE1 (operation S160 in FIG. 16).

A connection electrode layer is coated in the first openings OPE1 and then partially etched to form the connection electrodes 125. The connection electrodes 125 are spaced apart from the first common electrode CME1. A width W2 of each connection electrode 125 is smaller than that of each first opening OPE1.

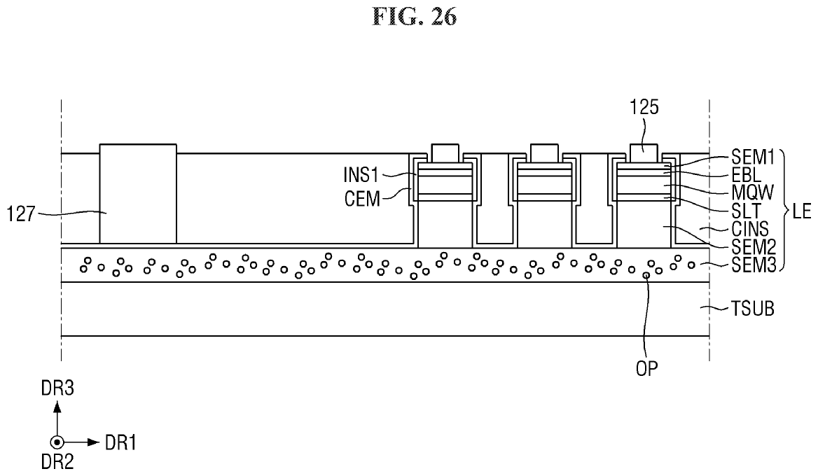

Referring to FIGS. 26 through 28, color conversion layers CCL2 and CCL3 are formed by forming pores OP by applying an electric field on the third semiconductor layer SEM3, and by then injecting wavelength conversion particles WCP2 and WCP3 (operation S170 in FIG. 16).

Once the pores OP are formed by applying an electric field on the third semiconductor layer SEM3, the target substrate TSUB is removed. The target substrate TSUB may be removed through a polishing process, such as a chemical mechanical polishing (CMP) process and/or an etching process.

Next, the third semiconductor layer SEM3 is etched to correspond to each light-emitting element LE. The third semiconductor layer SEM3 is etched such that an upper surface of the third semiconductor layer SEM3 is aligned with an upper surface of the second semiconductor layer SEM2 in contact with the third semiconductor layer SEM3.

Next, an organic material (e.g., a predetermined organic material) including second wavelength conversion particles WCP2 is injected into the pores OP of the third semiconductor layer SEM3 of a second light-emitting area EA2, and an organic material (e.g., a predetermined organic material) including third wavelength conversion particles WCP3 is injected into the pores OP of the third semiconductor layer SEM3 of a third light-emitting area EA3. Accordingly, the second wavelength conversion particles WCP2 may be located in the pores OP of the third semiconductor layer SEM3 of the second light-emitting area EA2. In addition, the third wavelength conversion particles WCP3 may be located in the pores OP of the third semiconductor layer SEM3 of the third light-emitting area EA3. The wavelength conversion particles WCP2 and WCP3 may have a diameter of several to several tens of nanometers. For example, the wavelength conversion particles WCP2 and WCP3 may be about 10 nm.

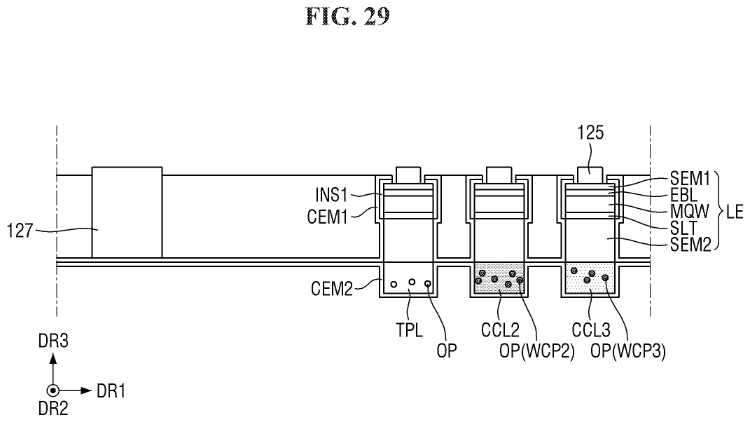

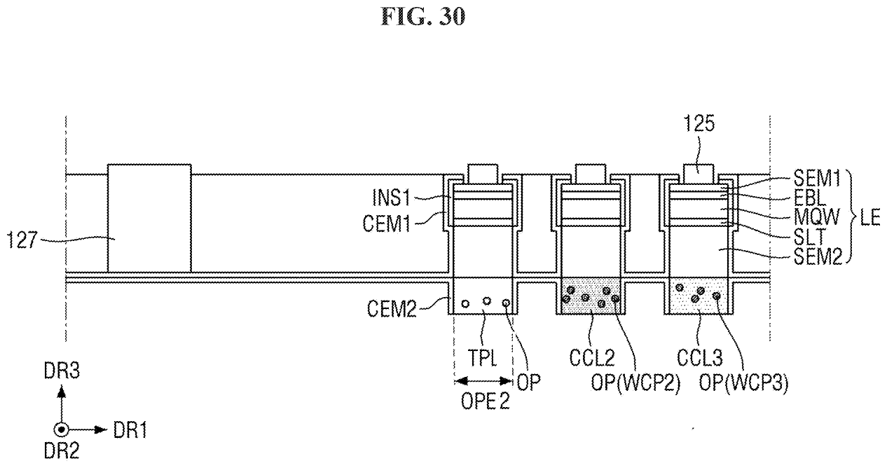

Referring to FIGS. 29 and 30, a second common electrode CME2 is formed to cover side surfaces of the color conversion layers CCL2 and CCL3, to contact the first common electrode CME1, and to have second openings OPE2 (operation S180 in FIG. 16).

First, the second common electrode CME2 is deposited on the first common electrode CME1 to cover the upper and side surfaces of the color conversion layers CCL2 and CCL3. Then, the second openings OPE2 are formed on the color conversion layers CCL2 and CCL3. That is, the second openings OPE2 may coincide with the entire upper surfaces of the color conversion layers CCL2 and CCL3. That is, the entire upper surfaces of the color conversion layers CCL2 and CCL3 may be exposed.

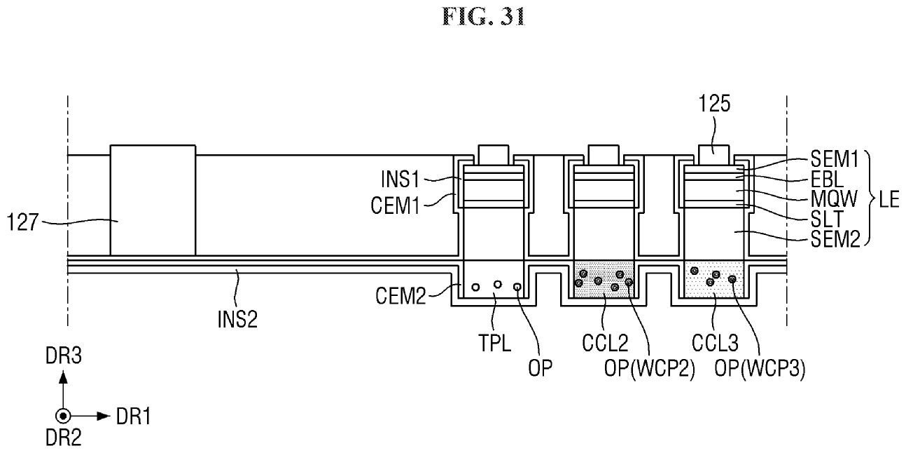

Referring to FIG. 31, a light-emitting element layer 120 is formed by forming a second insulating layer INS2 to cover the second common electrode CME2 (operation S190 in FIG. 16).

The second insulating layer INS2 is deposited on an upper surface of the second common electrode CME2 and the upper surfaces of the color conversion layers CCL2 and CCL3.

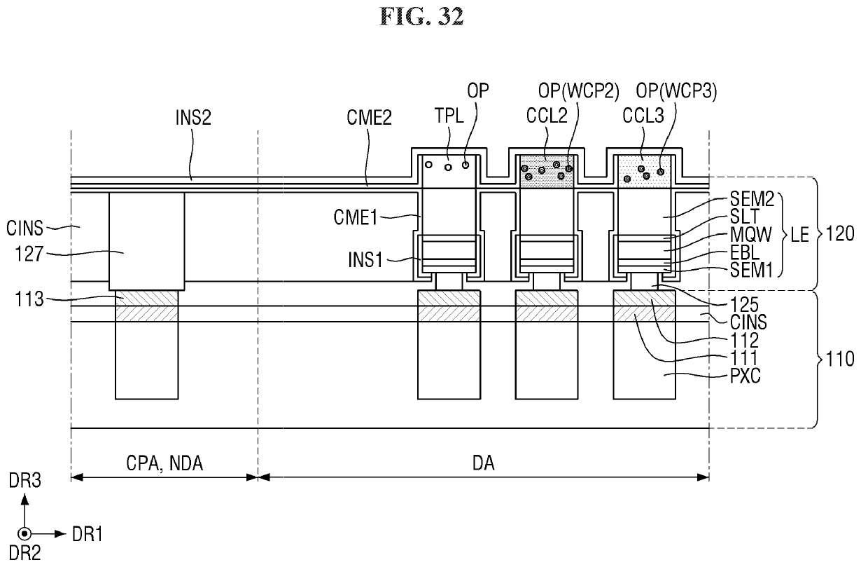

Referring to FIG. 32, the light-emitting element layer 120 is bonded to a semiconductor circuit board 110 (operation S200 in FIG. 16).

First, the semiconductor circuit board 110 is prepared. The semiconductor circuit board 110 may include a plurality of pixel circuit units PXC and pixel electrodes 111.

For example, the pixel electrodes 111 are formed on the semiconductor circuit board 110 on which the pixel circuit units PXC are formed. Then, the target substrate TSUB is aligned on the semiconductor circuit board 110. The semiconductor circuit board 110 and the target substrate TSUB may be aligned through alignment keys respectively located on them.

Next, the pixel electrodes 111 of the semiconductor circuit board 110 are brought into contact with the connection electrodes 125 of the light-emitting elements LE1, LE2, and LE3, respectively. Then, the light-emitting elements LE1, LE2, and LE3 are bonded to the semiconductor circuit board 110 by melt-bonding the pixel electrodes 111 and the connection electrodes 125 at a temperature (e.g., a predetermined temperature).

As described above, a display device according to embodiments can improve its color gamut by reducing or preventing light intruding between light-emitting areas, which may otherwise cause color mixing, by using a common electrode surrounding the light-emitting areas without using a separate reflector.

According to a display device according to embodiments, in a display panel having a color adjustment layer using a third semiconductor layer, a common electrode surrounding side surfaces of light-emitting elements and color conversion layers reduces or prevents color mixing of light, thereby improving color gamut.

However, the aspects of the present disclosure are not restricted to the one set forth herein. The above and other aspects of the present disclosure will become more apparent to one of daily skill in the art to which the present disclosure pertains by referencing the claims, with functional equivalents thereof to be included therein.

FIG. 33 is an example diagram illustrating a virtual reality device including a display device according to one or more embodiments. FIG. 33 illustrates a virtual reality device 1 in which the display device 10 according to one or more embodiments is used.

Referring to FIG. 33, the virtual reality device 1 according to one or more embodiments may be a device in a form of glasses. The virtual reality device 1 according to one or more embodiments may include a display device 10, a left-eye lens 10a, a right-eye lens 10b, a support frame 20, left and right legs 30a and 30b, a reflective member 40, and a display device housing 50.

FIG. 33 illustrates the virtual reality device 1 including the two legs 30a and 30b. However, the present disclosure is not limited thereto. The virtual reality device 1 according to one or more embodiments may be used in a head-mounted display including a head-mounted band that may be mounted on a head instead of the legs 30a and 30b. For example, the virtual reality device 1 according to one or more embodiments may not be limited to the example shown in FIG. 33, and may be applied in various forms and in various electronic devices.

The display device housing 50 may receive the display device 10 and the reflective member 40. An image displayed on the display device 10 may be reflected from the reflective member 40, and may be provided to a user's right eye through the right-eye lens 10b. Thus, the user may view a virtual reality image displayed on the display device 10 via the right eye.

FIG. 33 illustrates that the display device housing 50 is located at a right end of the support frame 20. However, the present disclosure is not limited thereto. For example, the display device housing 50 may be located at a left end of the support frame 20. In this case, the image displayed on the display device 10 may be reflected from the reflective member 40 and provided to the user's left eye via the left-eye lens 10a. Thus, the user may view the virtual reality image displayed on the display device 10 via the left eye. As another example, the display device housing 50 may be located at each of the left end and the right end of the support frame 20. In this case, the user may view the virtual reality image displayed on the display device 10 via both the left eye and the right eye.

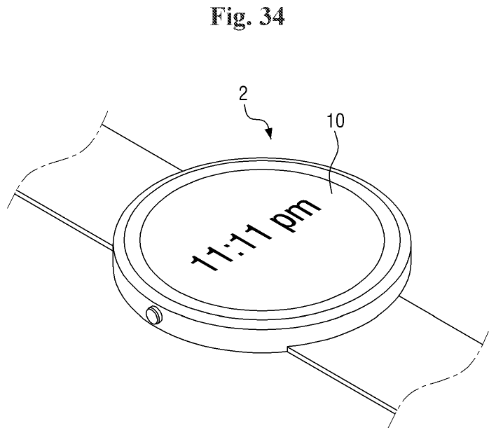

FIG. 34 is an example diagram illustrating a smart device including a display device according to one or more embodiments.

Referring to FIG. 34, a display device 10 according to one or more embodiments may be applied to a smart watch 2 as one of smart devices.

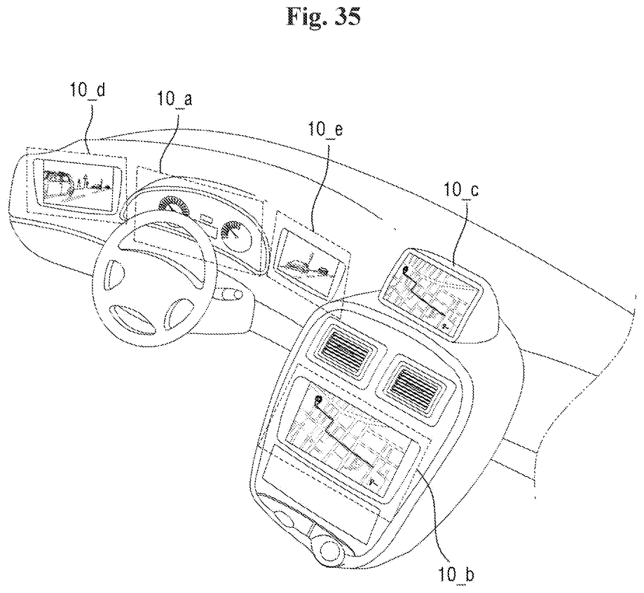

FIG. 34 is an example diagram illustrating a vehicle including a display device according to one or more embodiments. FIG. 35 illustrates a vehicle in which display devices according to one or more embodiments are used.

Referring to FIG. 35, the display devices 10_a, 10_b, and 10_c according to one or more embodiments may be applied to the dashboard of the vehicle, applied to the center fascia of the vehicle, or applied to a CID (Center Information Display) located on the dashboard of the vehicle. Further, each of the display devices 10_d and 10_e according to one or more embodiments may be applied to each room mirror display that replaces each of side-view mirrors of the vehicle.

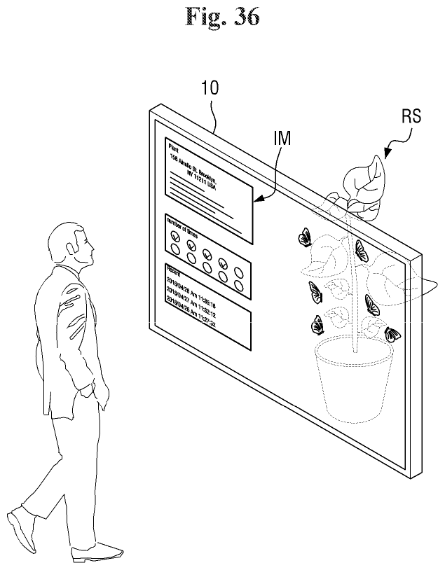

FIG. 36 is an example diagram illustrating a transparent display device including a display device according to one or more embodiments.

Referring to FIG. 36, a display device according to one or more embodiments may be applied to a transparent display device. The transparent display device may transmit light therethrough while displaying an image IM thereon. Therefore, a user located in front of the transparent display device may not only view the image IM displayed on the display device 10, but also view an object RS or a background located in rear of the transparent display device. In case that the display device 10 is applied to the transparent display device, the first substrate (e.g., the semiconductor circuit board 110) of the display 100 shown in FIG. 4 may include a light-transmitting portion that may transmit light therethrough, or may be made of a material that may transmit light therethrough.

In concluding the detailed description, those skilled in the art will appreciate that many variations and modifications can be made to the embodiments without substantially departing from the scope of the present disclosure. Therefore, the embodiments of the present disclosure are used in a generic and descriptive sense only and not for purposes of limitation.

What is claimed is:

1. A display device comprising:
a substrate comprising a display area and a non-display area;
a pixel electrode above the substrate;
a light-emitting element above the pixel electrode, and extending in a thickness direction of the substrate;
a color conversion layer above the light-emitting element, and comprising wavelength conversion particles for converting first light from the light-emitting element into second light or third light; and
a common electrode on the light-emitting element, and surrounding side surfaces of the color conversion layer and side surfaces of the light-emitting element.

2. The display device of claim 1, wherein the common electrode comprises a reflective material.

3. The display device of claim 1, wherein the color conversion layer comprises a third semiconductor layer defining pores that accommodate the wavelength conversion particles.

4. The display device of claim 1, wherein the light-emitting element sequentially comprises a first semiconductor layer, an active layer, and a second semiconductor layer.

5. The display device of claim 4, further comprising a first insulating layer surrounding side surfaces of the first semiconductor layer and the active layer.

6. The display device of claim 5, wherein the common electrode comprises:
a first common electrode on the first insulating layer to surround the side surfaces of the first semiconductor layer and the active layer, directly contacting the second semiconductor layer, and covering a non-light-emitting area of the display area; and
a second common electrode surrounding the side surfaces of the color conversion layer, and covering the non-light-emitting area of the display area,
wherein the non-light-emitting area is a portion of the display area excluding a light-emitting area corresponding to the light-emitting element.

7. The display device of claim 6, wherein the second common electrode is on the first common electrode in the non-light-emitting area, and contacts the first common electrode in the non-light-emitting area.

8. The display device of claim 6, wherein the first common electrode covers a portion of a lower surface of the light-emitting element.

9. The display device of claim 8, wherein the light-emitting element further comprises a connection electrode below the lower surface, and electrically insulated from the first common electrode.

10. The display device of claim 9, wherein the first common electrode is spaced apart from the connection electrode.

11. The display device of claim 9, wherein the first common electrode is spaced apart from the connection electrode, and
wherein a second insulating layer fills a space between the first common electrode and the connection electrode.

12. The display device of claim 9, wherein the first common electrode contacts the connection electrode, and
wherein an oxide layer is in a contact area between the first common electrode and the connection electrode.

13. The display device of claim 1, further comprising a common connection electrode in the non-display area and contacting the common electrode.

14. A display device comprising:
a substrate comprising a pixel circuit;
a first light-emitting element, a second light-emitting element, and a third light-emitting element above the substrate, and each comprising a first semiconductor layer, an active layer, a second semiconductor layer, and a third semiconductor layer;
a first insulating layer surrounding the first semiconductor layer and the active layer of each of the first light-emitting element, the second light-emitting element, and the third light-emitting element; and
a common electrode continuously above the first light-emitting element, the second light-emitting element, and the third light-emitting element, comprising a reflective material, and on the first insulating layer to surround the first semiconductor layer, the active layer, the second semiconductor layer, and the third semiconductor layer of each of the first light-emitting element, the second light-emitting element, and the third light-emitting element.

15. The display device of claim 14, wherein the third semiconductor layer defines pores that accommodate wavelength conversion particles.

16. The display device of claim 15, wherein the first light-emitting element, the second light-emitting element, and the third light-emitting element are configured to emit first light,
wherein the third semiconductor layer of the second light-emitting element accommodates first wavelength conversion particles for converting the first light into second light in the pores, and
wherein the third semiconductor layer of the third light-emitting element accommodates second wavelength conversion particles for converting the first light into third light in the pores.

17. The display device of claim 16, further comprising a color filter for transmitting the first light is above the first light-emitting element, a color filter for transmitting the second light is above the second light-emitting element, and a color filter for transmitting the third light is above the third light-emitting element.

18. The display device of claim 14, wherein the common electrode comprises a first common electrode and a second common electrode,
wherein the first common electrode comprises:
a first portion on the first insulating layer to surround side surfaces of the first semiconductor layer and the active layer, and directly contacting the second semiconductor layer; and
a second portion covering a space between the light-emitting elements, and
wherein the second common electrode comprises:
a third portion surrounding side surfaces of the third semiconductor layer; and
a fourth portion covering the space between the light-emitting elements, and on the third portion to contact the third portion.

19. A method of manufacturing a display device, the method comprising:
sequentially forming a third semiconductor layer, a second semiconductor layer, an active layer, and a first semiconductor layer above a substrate;
forming light-emitting elements by etching the second semiconductor layer, the active layer, and the first semiconductor layer;
forming an insulating layer surrounding side surfaces of the first semiconductor layer and the active layer;
forming a first common electrode above the substrate covering the insulating layer and the second semiconductor layer, and defining an opening on a surface of each light-emitting element;
forming a color conversion layer defining pores by applying an electric field to the third semiconductor layer, etching the third semiconductor layer to correspond to each of the light-emitting elements, and injecting wavelength conversion particles; and
forming a second common electrode covering side surfaces of the color conversion layer, and contacting the first common electrode.

20. The method of claim 19, wherein the forming the color conversion layer comprises etching the third semiconductor layer such that an upper surface of the third semiconductor layer is aligned with an upper surface of the second semiconductor layer in contact with the third semiconductor layer.

21. The method of claim 19, wherein the forming the insulating layer comprises:
forming a sacrificial layer between the light-emitting elements to cover the third semiconductor layer and side surfaces of the second semiconductor layer;
forming the insulating layer to cover an upper surface and the side surfaces of the first semiconductor layer, side surfaces of the active layer, and an upper surface of the sacrificial layer;
anisotropically etching the insulating layer to cover the upper and side surfaces of the first semiconductor layer and the side surfaces of the active layer; and
removing the sacrificial layer.

22. The method of claim 19, wherein the forming of the first common electrode comprises:
forming a common electrode layer on the insulating layer;
forming an opening by removing portions of the insulating layer and the common electrode layer on an upper surface of the first semiconductor layer; and
forming a connection electrode on the opening.
